(19) United States
(12) Patent Application Publication
(10) Pub. No.: US 2013/0016557 A1
(43) Pub. Date: Jan. 17, 2013

(54) SEMICONDUCTOR MEMORY DEVICE HAVING A THREE-DIMENSIONAL STRUCTURE

(71) Applicant: Jin-Ki Kim, Ottawa (CA)

(72) Inventor: Jin-Ki Kim, Ottawa (CA)

(73) Assignee: Mosaid Technologies Incorporated, Ottawa, ON (CA)

(21) Appl. No.: 13/636,574

(22) PCT Filed: Apr. 4, 2011
(86) PCT No.: PCT/CA2011/000365

§ 371 Date: Sep. 21, 2012

Related U.S. Application Data
(60) Provisional application No. 61/320,973, filed on Apr. 5, 2010.

(51) Int. Cl. H01L 45/00; H01L 21/8239; G11C 11/34

(52) U.S. Cl. 365/163; 438/382; 257/4; 257/E21.004; 257/E21.645; 257/E45.001

(57) ABSTRACT

A three-dimensional memory device includes a stack of semiconductor layers. Phase change memory (PCM) cell arrays are formed on each layer. Each PCM cell includes a variable resistor as storage element, the resistance of which varies. On one layer, formed is peripheral circuitry which includes row and column decoders, sense amplifiers and global column selectors to control operation of the memory. Local bit lines and worldliness are connected to the memory cells. The global column selectors select global bitlines to be connected to local bit lines. The row decoder selects wordlines. Applied current flows through the memory cell connected to the selected local bitline and wordline. In write operation, set current or reset current is applied and the variable resistor of the selected PCM cell stores “data”. In read operation, read current is applied and voltage developed across the variable resistor is compared to a reference voltage to provide as read data.

### CROSS-REFERENCE TO RELATED APPLICATIONS

This application claims priority from U.S. Provisional Patent Application Ser. No. 61/320,973, filed on Apr. 5, 2010, entitled “3-DIMENSIONAL PHASE CHANGE MEMORY”, the entirety of which is incorporated by reference herein.

### TECHNICAL FIELD

The present invention relates generally to memory devices. More specifically, the present invention relates to a semiconductor memory device having a three-dimensional structure.

### BACKGROUND

Examples of nonvolatile memory devices are phase change memories (PCMs). PCMs use phase change materials, for example, such as chalcogenide, for storing data. A typical chalcogenide compound is Ge₂—Sb₂—Te₅ (GST). The phase change materials are capable of stably transitioning between crystalline and amorphous phases by controlling heating and cooling processes. The amorphous phase exhibits a relatively high resistance compared to the crystalline phase which exhibits a relatively low resistance. The amorphous state, also referred to as the “reset” state or logic “0” state, can be established by heating the GST compound above a melting temperature of 610° C., then rapidly cooling the compound. The crystalline state, which is referred to as the “set” state or logic “1” state, can be established by heating the GST compound above a crystallizing temperature for a longer period of time sufficient to transform the phase change material into the crystalline state. The crystallizing temperature is below the melting temperature of 610° C. The heating period is followed by a subsequent cooling period.

FIG. 1 depicts a typical phase change memory cell. Referring to FIG. 1, a phase change memory (PCM) cell 110 includes a storage element 112 and a switching element 114. The switching element 114 is used to selectively access the storage element 112 of the PCM cell 110. A typical example of the storage element 112 is a variable resistor formed by a phase change material (e.g., GST). The resistance of the variable resistor can be altered by transforming a structure (or a characteristic) between the crystalline and amorphous phases.

FIG. 2 shows a structure of an example storage element as the storage element 112 of PCM cell 110 shown in FIG. 1. Referring to FIG. 2, a heater 122 is located between a first electrode 124 and a chalcogenide compound 126 that is contacted by a second electrode 128, typically with low resistance. The first electrode 124 is used to make a low resistance contact to the heater 122. The heater 122 causes a portion of the chalcogenide compound 126 to transform from the crystalline state to the amorphous state in a physical space referred to as a programmable volume 132 shown in FIG. 2.

FIG. 3 shows the relationship of time and temperature for both reset and set programming of the storage element shown in FIG. 2 for the phase change memory. Referring to FIGS. 2 and 3, the phase change memory (PCM) cell can be programmed to two states (or phases): (i) the amorphous or “reset” state; and (ii) the crystalline or “set” state. Such programming of the states can be achieved by heating the phase change layer (the chalcogenide compound 126 of the storage element) by the heater 122. To program the reset state, the phase change layer is heated to a temperature T_Reset with a current I_Reset through the heater 122 for a duration of tP_Reset, then quickly cooling down the phase change layer. To program the set state, the phase change layer is heated to a temperature T_Set with a current I_Set through the heater 122 and to maintain the phase change layer at temperature T_Set for a duration of tP_Set and then cooling down the phase change layer. The time interval tP_Set of the current I_Set exceeds tP_Reset of the current I_Reset. Pulses of the applied currents I_Reset and I_Set are referenced at “232” and “234”, respectively.

FIGS. 4A and 4B show a phase change memory (PCM) in a programmed set state “SET” and a programmed reset state “RESET”, respectively. The phase change materials (or the phase change layers) are thermally activated. Referring to FIGS. 2, 3, 4A and 4B, the PCM cell is programmed to the set state by applying the current I_Set for the duration of tP_Set. The amount of heat applied to the phase change layer is proportional to I²×R, where “I” is a currency value of I_Set through the heater 122 and “R” is a resistance of the heater 122. While the PCM cell is being programmed to the set state (“SET”) as shown in FIG. 4A, the phase change layer is changed to the crystalline state, resulting in a lower cell resistance compared to the reset state (“RESET”) as shown in FIG. 4B. Similarly, the phase change memory cell is programmed to the reset state by applying the current I_Reset for the duration of tP_Reset. While the PCM cell is being programmed to the reset state, a certain volume of phase change layer is changed to the amorphous state (of FIG. 4B), resulting in a higher cell resistance than the set state (of FIG. 4A). The programmable volume in the phase change layer is generally a function of the amount of heat applied to the phase change layer.

Phase change memory devices typically use the amorphous state to represent a logical “0” state (or RESET state) and the crystalline state to represent a logical “1” state (or SET state). Table 1 summarizes typical properties of an example phase change memory.

TABLE 1
Phase Change Memory Properties

| Data | “0” | “1” |
|---|---|---|
| Program State | Reset | Set |
| Resistance | High (>100 KΩ) | Low (10 KΩ) |
| Read Current | Low | High |
| Material Phase | Amorphous | Crystalline |
| Write Pulse | Approximately 50 ns | Approximately 200 ns |
| | (tP_Reset) | (tP_Set) |

In recent years, various phase change memory (PCM) cells have been used. FIG. 5 shows a diode based PCM cell that includes a diode 144 connected to a storage element 142. The cathode of the diode 144 is connected to a wordline 148. The storage element 142 is connected to a bitline 146. The diode 144 is a two-terminal device. Tree-terminal devices can also be used as the switching elements. FIG. 6 shows a FET (or MOS transistor) based PCM cell that includes a FET (MOS transistor) 154 and a storage element 152. The gate, drain and source of the transistor 154 are connected to a wordline 158, the storage element 152 and the ground, respectively. The storage element 152 is connected to a bitline 156. FIG. 7 shows a bipolar transistor based PCM cell that includes a bipolar transistor (of PNP type) 164 and a storage element 162. The base, emitter and collector of the bipolar transistor 164 are connected to a wordline 168, the storage element 162 and the ground, respectively. The storage element 162 is connected to a bitline 166.

A memory cell array can be formed by a plurality of PCM cells shown in FIG. 5, which are connected to a plurality of bitlines 146 and wordlines 148. Similarly, a memory cell array can be formed by a plurality of PCM cells shown in FIG. 6, which are connected to a plurality of bitlines 156 and wordlines 158. A memory cell array can be formed by a plurality of PCM cell arrays shown in FIG. 7, which are connected to a plurality of bitlines 166 and wordlines 168.

Each of the storage elements 142, 152, and 162 is formed by a variable resistor that functions as the storage element 112 as shown in FIG. 1. Each of the diode 144, MOS transistor 154, and bipolar transistor 164 functions as the switching element 114 shown in FIG. 1 and functions as an access element to the storage element connected thereto.

To use the diode 144 shown in FIG. 5 or the bipolar transistor 164 shown in FIG. 7, as the switching element 114 in the memory cell, is an attempt to reduce cell size, so as to improve memory density. Further improvements in memory system density are needed to continue to reduce memory system cost and increase memory capacity driven in part by increased data traffic in electronic systems.

### SUMMARY

According to one aspect of the present invention, there is provided a method of fabricating a memory device. By the method, a stack of semiconductor layers is formed. Also, by the method, a circuit is formed on a layer of the stack of semiconductor layers. A primary memory array is formed on another layer of the stack of semiconductor layers different from the layer comprising the circuit. A plurality of electrical communication paths are formed between the circuit and the primary memory array. The circuit is to control operation of the primary memory array over the electrical communication paths.

According to another aspect of the present invention, there is provided a memory device comprising a stack of semiconductor layers. The memory comprises a circuit formed on a layer of the stack of semiconductor layers. A primary memory array is on another layer of the stack of semiconductor layers different from the layer comprising the circuit. A plurality of electrical communication paths are between the circuit and the primary memory array. The circuit controls the operation of the primary memory array over the electrical communication paths.

For example, the primary memory array comprises a phase change memory or a plurality of memory cells. Each of the plurality of memory cells may comprise a diode connected to a variable resistive element, a field-effect transistor connected to a variable resistive element, or a bipolar transistor connected to a variable resistive element.

According to another aspect of the present invention, there is provided a memory device comprising a base semiconductor layer comprising a plurality of memory control circuits. A stack of semiconductor layers is formed over the base semiconductor layer. Each layer of the stack of semiconductor layers includes a memory array in communication with one of the plurality of memory control circuits.

According to another aspect of the present invention, there is provided a memory device comprising a stack of m layers, each layer including an array of memory cells formed thereon, the array having k rows×c columns of cells, each of m, k and c being an integer greater than one, each of the memory cells including a phage change memory cell.

For example, the phase change memory array includes a diode, a field-effect transistor or a bipolar transistor connected to a variable resistive element functioning as a storage element.

The memory device may further comprise peripheral circuitry for controlling operation of the memory cells formed on one of the layers. The peripheral circuitry and the memory cell array on one of the layers may be formed on a common semiconductor substrate.

For example, peripheral circuitry may include row decoders and column selectors for selecting wordline and bitline in the cell array. A memory cell connected to the selected wordline and bitline is accessed for data write or data read. The memory cell may be a phase change memory including a variable resistor as a storage element. In a write operation, a set current is applied and the variable resistor stores “data”. In a read operation, developed voltage by the variable resistor is compared to a reference voltage to provide as read data in the read operation.

In an embodiment of the present invention, there is provided a three-dimensional phase change memory (PCM) device. The PCM device includes a plurality of (m) semiconductor (e.g., silicon (Si)) layers on which a plurality of stacked PCM cell arrays is formed. For example, on each of the plurality of semiconductor arrays, a plurality of (p groups) arrays of PCM cells is formed. One group of PCM cell array is repeated and the groups of PCM cell arrays are formed side-by-side on the respective layers. The p groups of PCM cell arrays are formed on the first layer and the p groups of PCM cells are formed on the second layer. Similarly, the p groups of the other PCM cell arrays are formed on respective semiconductor layers.

The PCM device may include array control circuits, such as, for example, row decoders and local column decoders. The local column decoders perform local column selection. The local column selectors corresponding to the PCM cell arrays of the first array, second array and p-th are repeated for the m layers side-by-side on the first semiconductor layer.

The PCM device may further include global column decoders. The global column decoders are formed on the first semiconductor layer. The row decoders are also formed on the first semiconductor layer.

In another embodiment, all peripheral control circuits are formed on the first semiconductor layer.

According to embodiments of the present invention, there is provided PCM devices and systems, and related three-dimensional device architecture having stacked multiple cell arrays on multiple semiconductor layers. The multiple cell arrays improve the memory density and the memory capacity used in a memory system.

Memory devices according embodiments of the present invention may include other type memories, for example, such as, random access memory (RAM) and read only memory (ROM). RAM may include magnetic RAM (MRAM), resistive RAM (RRAM), and ferroelectric RAM (FRAM).

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

Embodiments of the present invention will now be described, by way of example only, with reference to the attached Figures, wherein:

FIG. 1 is a schematic diagram illustrating a phase change memory (PCM) cell;

FIG. 2 is a cross-sectional view showing a structure of a PCM cell;

FIG. 3 is a graph of temperature change during set and reset operations of a PCM cell;

FIGS. 4A and 4B are cross-sectional views of the PCM in the set state and the reset state, respectively;

FIG. 5 is a schematic diagram illustrating a diode based PCM cell;

FIG. 6 is a schematic diagram illustrating a FET transistor based PCM cell;

FIG. 7 is a schematic diagram illustrating a bipolar transistor based PCM cell;

FIG. 8 is a schematic diagram illustrating a memory device to which embodiments of the present invention are applicable;

FIG. 9A is a cross-sectional view of a memory device including a plurality of diode based PCM cells according to an embodiment of the present invention;

FIG. 9B is a cross-sectional view of a three-dimensional diode based PCM according to another embodiment of the present invention;

FIG. 10 is a schematic diagram illustrating PCM cell arrays included in the memory device according to an embodiment of the present invention;

FIG. 11 is a schematic diagram illustrating the PCM cell array shown in FIG. 10 with write operation;

FIG. 12 is a schematic diagram illustrating the PCM cell array shown in FIG. 10 with read operation;

FIG. 13A is a block diagram illustrating a three-dimensional memory architecture having a plurality of PCM cells according to an embodiment of the present invention;

FIG. 13B is a schematic diagram illustrating memory address control signals for the three-dimensional memory architecture shown in FIG. 13A;

FIG. 14 is a schematic diagram illustrating an example of a local column selector of the three-dimensional memory shown in FIG. 13A;

FIG. 15 is a schematic diagram illustrating an example of a global column selector of the three-dimensional memory shown in FIG. 13A;

FIG. 16 is a schematic diagram illustrating an example of a write driver of the three-dimensional memory shown in FIG. 13A;

FIG. 17 is a schematic diagram illustrating an example of a sense amplifier of the three-dimensional memory shown in FIG. 13A;

FIG. 18 is a schematic diagram illustrating an example of a row decoder of the three-dimensional memory shown in FIG. 13A;

FIG. 19A is a schematic diagram illustrating a circuit performing a write operation of the three-dimensional memory according to an embodiment of the invention;

FIG. 19B is a schematic diagram illustrating a circuit performing a read operation of the three-dimensional memory according to an embodiment of the invention;

FIG. 20A is a timing diagram illustrating a write operation of the three-dimensional memory according to an embodiment of the invention;

FIG. 20B is a timing diagram illustrating a read operation of the three-dimensional memory according to an embodiment of the invention;

FIG. 21 is a block diagram illustrating a three-dimensional memory architecture having a plurality of PCM cells according to another embodiment of the present invention;

FIG. 22 is a schematic diagram illustrating an example of a global column selector of the three-dimensional memory shown in FIG. 21;

FIG. 23 is a schematic diagram illustrating an example of a write driver of the three-dimensional memory shown in FIG. 21;

FIG. 24 is a schematic diagram illustrating another example of a sense amplifier of the three-dimensional memory shown in FIG. 21;

FIG. 25A is a block diagram illustrating a three-dimensional memory architecture with segmented arrays according to another embodiment of the present invention;

FIG. 25B is a schematic diagram illustrating memory address control signals for the three-dimensional memory architecture shown in FIG. 25A; and

FIGS. 26A and 26B are schematic diagrams illustrating PCM cell arrays applicable to memory devices according to embodiments of the present invention.

### DETAILED DESCRIPTION

Generally, embodiments of the present invention relate to semiconductor memory device. Embodiments of the present invention relate to phase change memory (PCM) devices and systems, and related three-dimensional device architecture having stacked multiple cell arrays on multiple semiconductor (e.g., Si) layers.

In one embodiment, a PCM cell uses a diode as the switching element of a phase change memory cell. In other embodiments, the switching element is a MOS transistor and a bipolar transistor. In embodiments, memory devices are volatile and nonvolatile memories. Memory devices include various types of memories, such as, for example, random access memory (RAM) and read only memory (ROM). RAMs include, for example, magnetic RAM (MRAM), resistive RAM (RRAM), and ferroelectric RAM (FRAM).

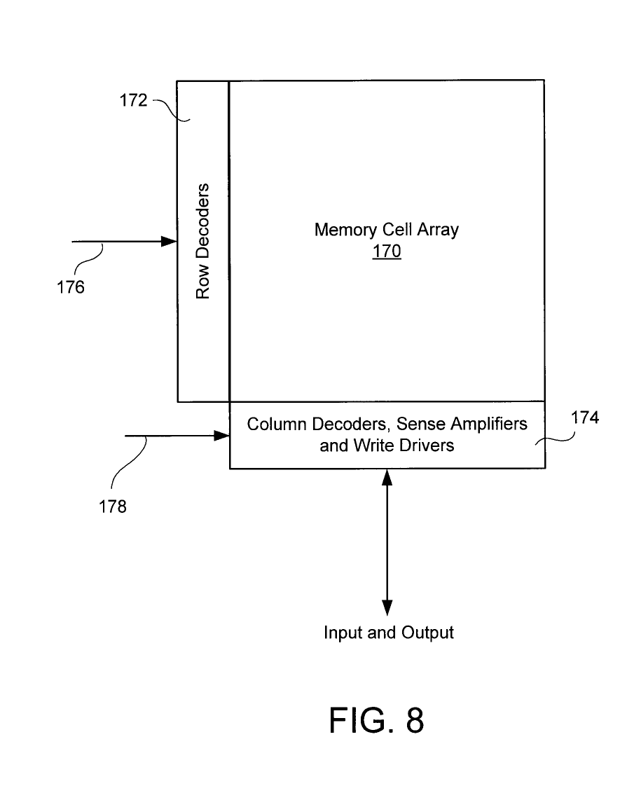

FIG. 8 shows a memory device to which embodiments of the present invention are applicable. Referring to FIG. 8, a memory device includes a memory cell array 170 with peripheral circuitry including row decoders 172 and column decoders, sense amplifiers and write drivers 174. The row decoders 172 receive signals 176 including pre-decoded address information and control information. The column decoders, sense amplifiers and write drivers 174 receive signals 178 including control information. Also, the column decoders, sense amplifiers and write drivers 174 communicate with input and output (I/O) circuits (not shown) for data write and read. The control information for the rows (wordlines) and columns (bitlines) is provided by memory device control circuitry (not shown).

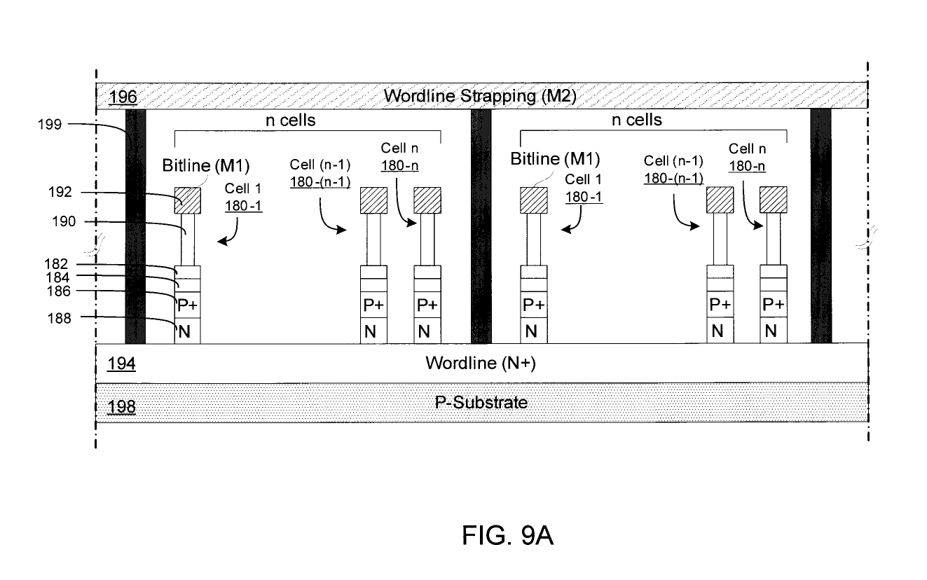

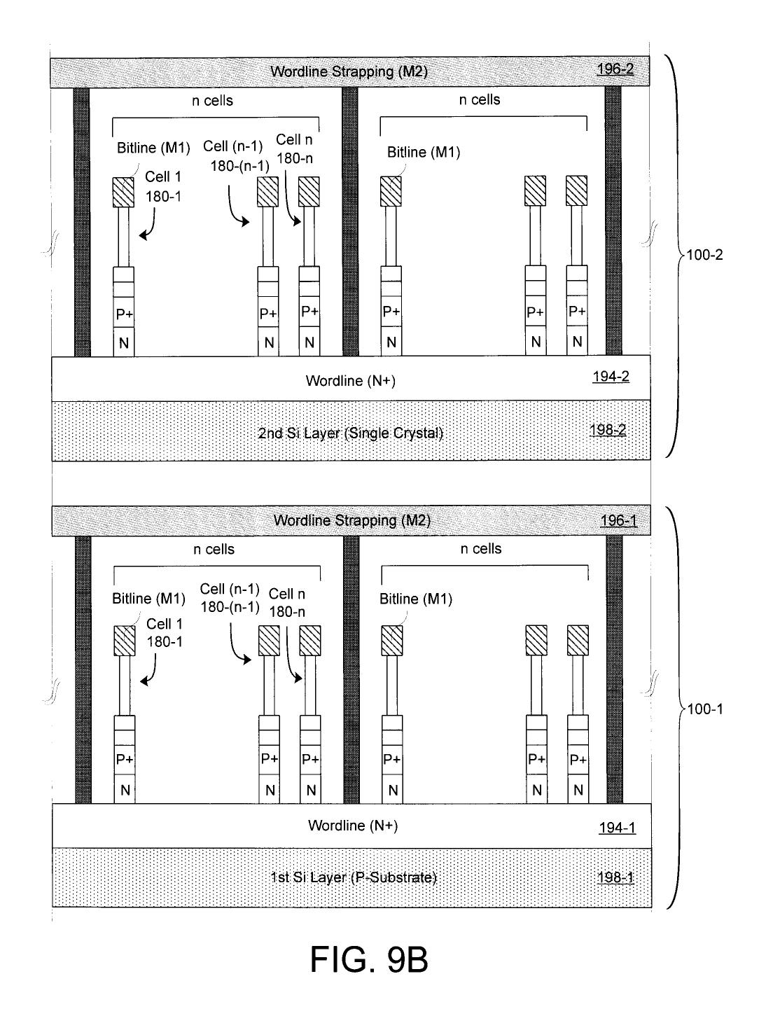

FIG. 9A shows a memory device including a plurality of diode based phase change memory (PCM) cells according to an embodiment of the present invention. Referring to FIG. 9A, the device has a plurality of groups of cell arrays, each group comprising cell 1, . . . , cell (n−1), cell n. In the particular example, n memory cells 180-1, . . . , 180-(n−1) and 180-n are repeated to form one layer of cell arrays, n being an integer greater than one. For example, n is 64, but it is not limited. Each of the n memory cells 180-1, . . . , 180-(n−1) and 180-n is configured with GST (chalcogenide compound) 182, a self-aligned bottom electrode 184 and a vertical P-N diode connected in series as an anode 186 and a cathode 188. A heater 190 is between the GST 182 and a bitline 192 with a top electrode (not shown), which is configured with low resistance.

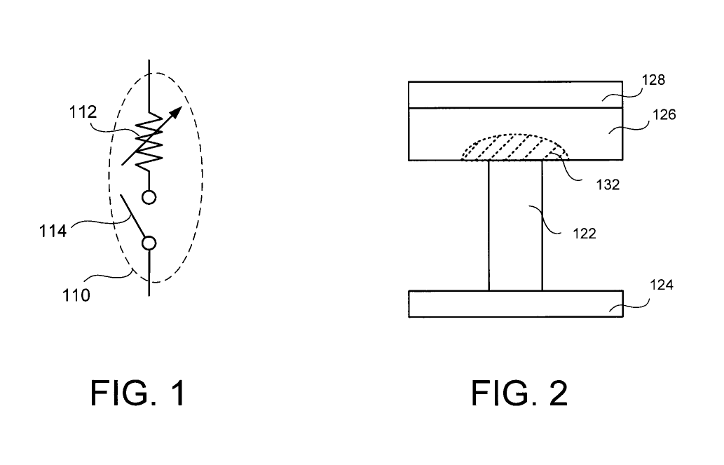

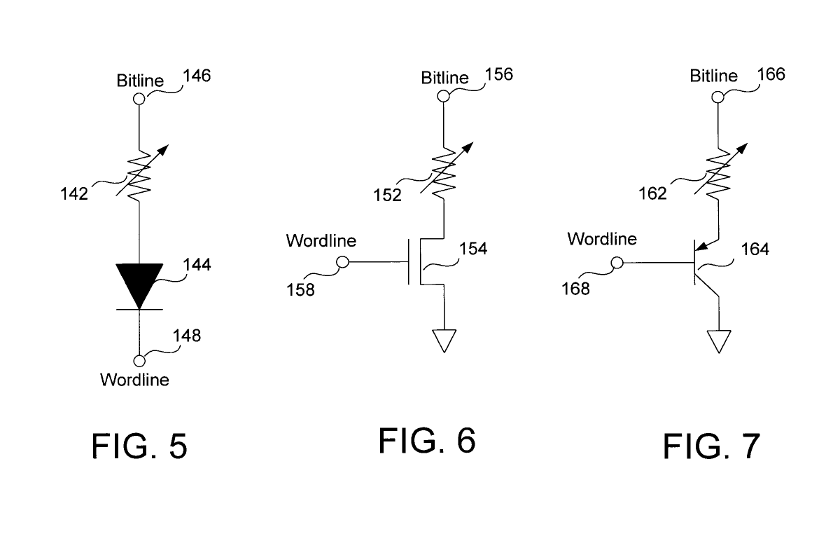

The heater 190 corresponds to the heater 122 of FIGS. 2 and 4A, 4B. The GST 182 corresponds to the chalcogenide compound 126 of FIGS. 2 and 4A, 4B. The top electrode, which is the contact of the heater 190 and the bitline 192, and the bottom electrode 184 correspond to the first electrode 124 and the second electrode 128 of FIGS. 2 and 4A, 4B, respectively. The chalcogenide compound develops the programmable volume 132 as shown in FIGS. 2 and 4B. The diode having the anode 186 and cathode 188 corresponds to the diode 144 shown in FIG. 5 and functions as the switching element 114 of FIG. 1.

The bitline 192 formed by a first metal layer (M1). The cathode 188 of the diode is connected to a wordline 194 formed in an N+ doped base of a P substrate 198. In the particular example, the substrate 198 is formed by a semiconductor layer with a P-type dopant. A wordline strap 196 uses a second metal layer (M2) to reduce the word line resistance. A wordline strap can be used for every n phase change memory (PCM) cells. The choice of how often to connect (e.g., “strap”) the word line 194 with the low resistance strap 196 is made by strapping enough to lower the wordline resistance between a wordline driver (described later) and the memory cell that is the furthest from the strap connection. The strapping is not, however, made to significantly increase the overall memory array size. The wordline 194 and the strap 196 are connected by a contact 199. The bitline 192 and the wordline 194 correspond to the bitline 146 and the wordline 148, respectively, shown in FIG. 5. In the cases where the FET and bipolar based PCM cells are implemented, the bitline 192 corresponds to each of the bitlines 156 and 166 and the wordline 194 corresponds to each of the wordlines 158 and 168 shown in FIGS. 6 and 7.

FIG. 9B shows a three-dimensional memory device according to another embodiment of the present invention. In the particular example shown in FIG. 9B, a three-dimensional memory device includes two stacked PCM structures 100-1 and 100-2. The PCM structure 100-1 includes a first silicon layer 198-1 of P-substrate. The PCM structure 100-2 includes a second silicon layer 198-2 of single crystal. The layers 198-1 and 198-2 can use semiconductor materials including GaAs and “III-V” compound materials. Each of the stacked PCM structures 100-1 and 100-2 has a plurality of PCM cells that have the same structure of the diode based PCM cells as shown in FIG. 9A. The PCM structures 100-1 and 100-2 include respective wordlines 194-1, 194-2 and wordline straps 196-1, 196-2.

The PCM cell arrays of the first layer 100-1 are fabricated on the P-substrate 198-1 (the first semiconductor layer). The PCM cell arrays of the second layer 100-2 are fabricated on the second semiconductor layer 198-2. Additional structures of PCM cell arrays may be fabricated on layers formed over the PCM structure 100-2. A person skilled in the art would understand that the number of layers of the stacked structure is not limited.

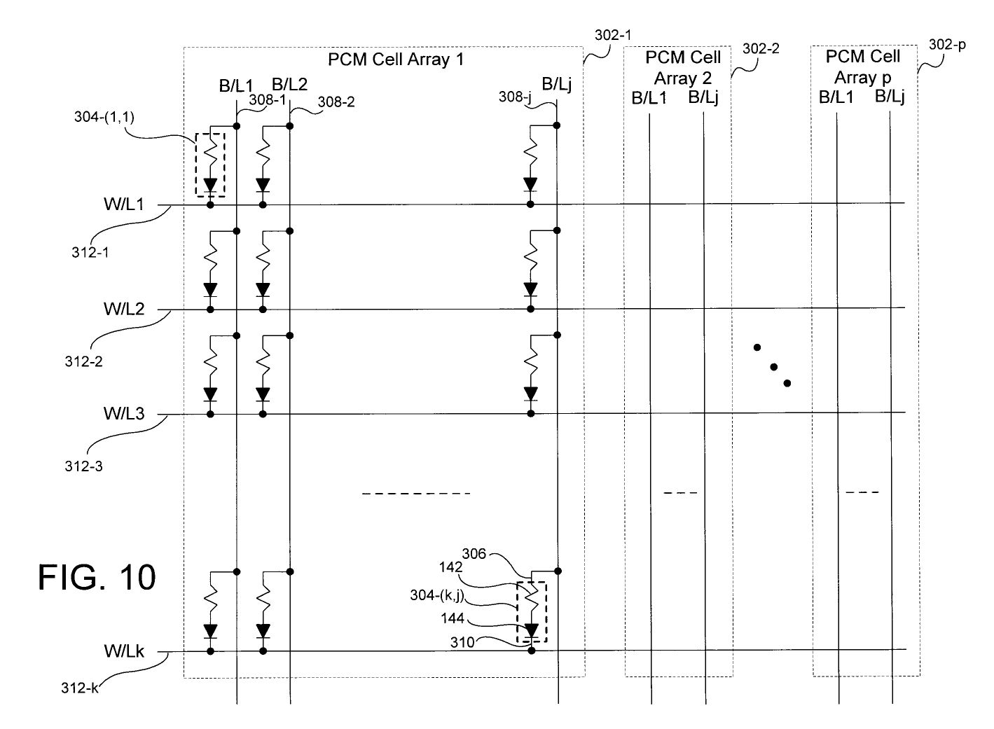

FIG. 10 shows phase change memory (PCM) cell arrays included in a memory device according to an embodiment of the present invention. The memory device has a three-dimensional structure as shown in FIGS. 9A and 9B. In the particular example shown in FIG. 10, memory cells are diode based PCM cells. Each of the memory cells includes a diode 144 and a variable resistor 142 as a storage element as shown in FIG. 5.

Referring to FIGS. 9A, 9B and 10, a plurality of (p) cell arrays (PCM cell array 1, PCM cell array 2, . . . , PCM cell array p) are fabricated on one semiconductor layer (e.g., each of the layers 198-1 and 198-2 in FIG. 9B), p being an integer greater than one. For example, p is 4 or 8. Circuit structure of the PCM cell arrays is identical to each other. Each group of the p PCM cell arrays 302-1-302-p includes a plurality of (j) bitlines (B/L1-B/Lj). A plurality of (k) wordlines “W/L1”-“W/Lk” 312-1-312-k is connected to PCM cells of the PCM cell arrays 302-1-302-p. Each of the PCM cell arrays includes a plurality of memory cells (k×j cells), k and j representing row and column numbers, respectively, each of k and j being an integer greater than one. For example, k is 512 and j is 256. Each of the memory cells includes a diode connected to a storage element, such as, for example, a diode based PCM cell including the diode 144 connected to the storage element 142 as shown in FIG. 5. A person skilled in the art would understand that p, k and j are not limited.

In FIG. 10, each of the storage elements is represented by a resistor (which is actually the variable resistor 142 as shown in FIG. 5). In general, a memory cell connected to a wordline and a bitline is represented by “304-(K,J)”, K representing the variable number of row of one layer, J representing the variable number of column in one of the p groups, 1≦K≦k, 1≦J≦j. In FIG. 10, memory cells 304-(1,1) and 304-(k,j) are shown. Each memory cell is coupled to a bitline and a wordline at a cross point thereof. Each of the memory cells has a first terminal 306 and a second terminal 310. The first terminal 306 corresponds to the first electrode 124 shown in FIGS. 2, 4A, 4B and the connection of the bitline 192 and the heater 190 shown in FIG. 9A. FIG. 10 does not, however, show a heater connected to the variable resistor of a memory cell. The second terminal 310 corresponds to a junction of the cathode 188 and the wordline 194 as shown in FIG. 9A. The first and second terminals 306 and 310 of the memory cell 304-(k,j) as shown in FIG. 10 are connected to corresponding bitline “B/Lj” 308-j and wordline “W/Lk” 312-k, respectively. The bitlines are also referred to as “columns” and the wordlines are referred to as “rows.” The number of the columns in one cell array, j, is not limited and j may be equal to n that represents the number of PCM cells in a row within one array as shown in FIGS. 9A, 9B. An example of j is 256. The number of the rows in one cell array, k, and the number of arrays, p, are not limited.

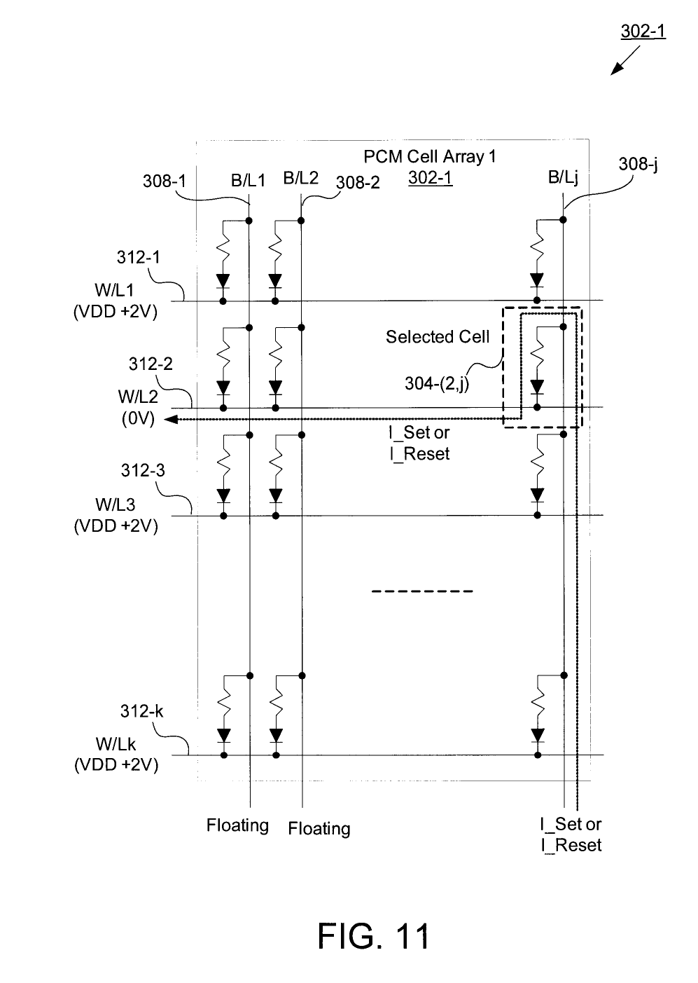

FIG. 11 shows one of the PCM cell arrays (e.g., PCM cell array 1, 302-1) shown in FIG. 10 for the purpose of describing a write operation “WRITE”. The selection of wordline and bitline is performed in accordance with the row and column addresses. In the particular example shown in FIG. 11, wordline “W/L2” and bitline “B/Lj” are selected.

Referring to FIG. 11, wordline “W/L2” 312-2 is selected by changing its bias to 0V, while each of wordlines 312-1 and 312-3-312-k remains unselected with a bias of VDD+2 volts. In the particular example shown in FIG. 11, the voltage of VDD is 1.8 volts and the technology uses a 0.18 μm minimum feature size. However, a person skilled in the art would understand that other voltages, process technologies and cell characteristics are possible. Write current with a value of “I_Reset” or “I_Set” from a write driver (described later) flows through a selected bitline “B/Lj” 308-j and the selected wordline “W/L2” 312-2 via the selected cell 304-(2,j). Unselected bitlines (e.g., bitlines 308-1, 308-2 and others not shown) are left in a high impedance “floating” state, with the bitline potential held up by the parasitic capacitance of the bitline. Unselected cells connected to unselected wordlines or floating bitlines are reverse biased and thus, no current flows through the unselected cells. The selected cell 304-(2,j) is used for writing data “1” by set current I_Set, or “0” by reset current I_Reset.

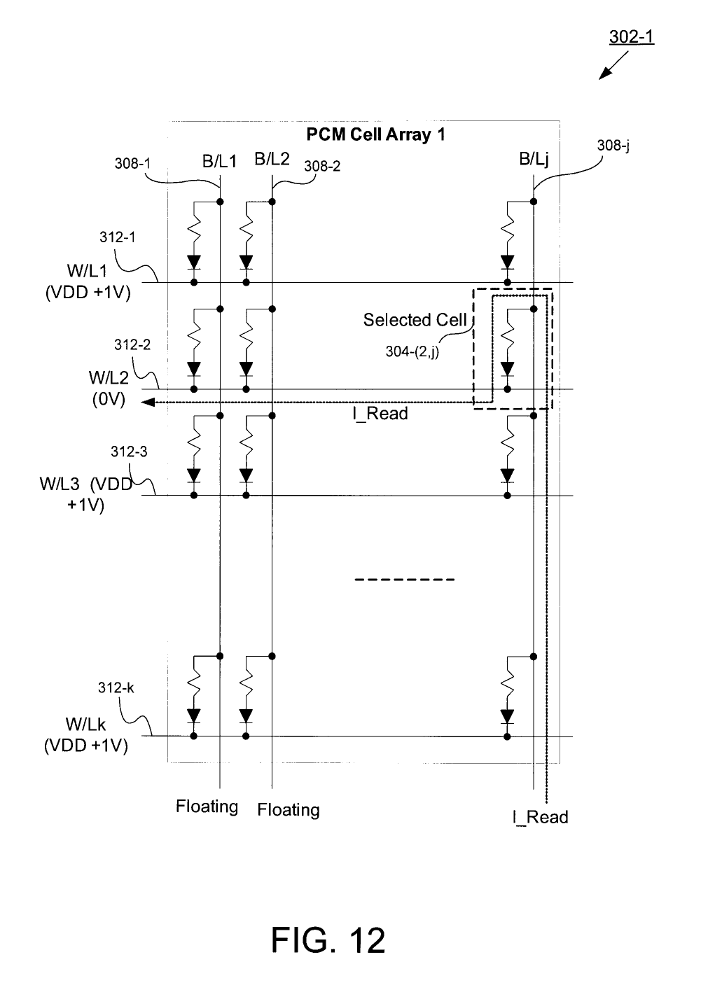

FIG. 12 shows PCM cell array 1, 302-1, of FIG. 10, biased for a read operation “READ”. Referring to FIG. 12, wordline “W/L2” 312-2 is selected by changing its bias to 0V, while the unselected wordlines 312-1 and 312-3-312-k remain unselected with a bias of VDD+1 volt. Read current “I_Read” from a sense amplifier (described later) flows to the selected wordline “W/L2” 312-2 through the selected bitline “B/Lj” 308-j and the selected cell 304-(2,j). Unselected bitlines (e.g., bitlines 308-1, 308-2 and others (not shown)) are left in a high impedance “floating” state, with the bitline potential held up by the parasitic capacitance of the bitline. Unselected cells connected to unselected wordlines or floating bitlines are reverse biased and thus, no current flows through the unselected cells.

An example of voltage bias conditions and current conditions for diode based PCM devices as shown in FIGS. 10, 11 and 12 are summarized in Table 2 (Kwang-Jin Lee et al., “A 90 nm 1.8 V 512 Mb Diode-Switch PRAM With 266 MB/s Read Throughput,” IEEE J Solid-State Circuits, vol. 43, no. 1, pp. 150-162, January 2008). All voltage and current values are examples for the embodiments. A person skilled in the art would understand that other values consistent with a process technology and cell characteristic are possible.

TABLE 2
Voltage and Current Conditions for a Diode Based PCM

| | Reset Write | Set Write | Read |
|---|---|---|---|
| Voltage applied to | VDD + 2 V | VDD + 2 V | VDD + 1 V |
| Unselected W/L | | | |
| Voltage applied to | 0 V | 0 V | 0 V |
| Selected W/L | | | |
| Condition of | Floating | Floating | Floating |
| Unselected B/L | | | |
| Current flowing through | I_Reset | I_Set | I_Read |
| Selected B/L | | | |

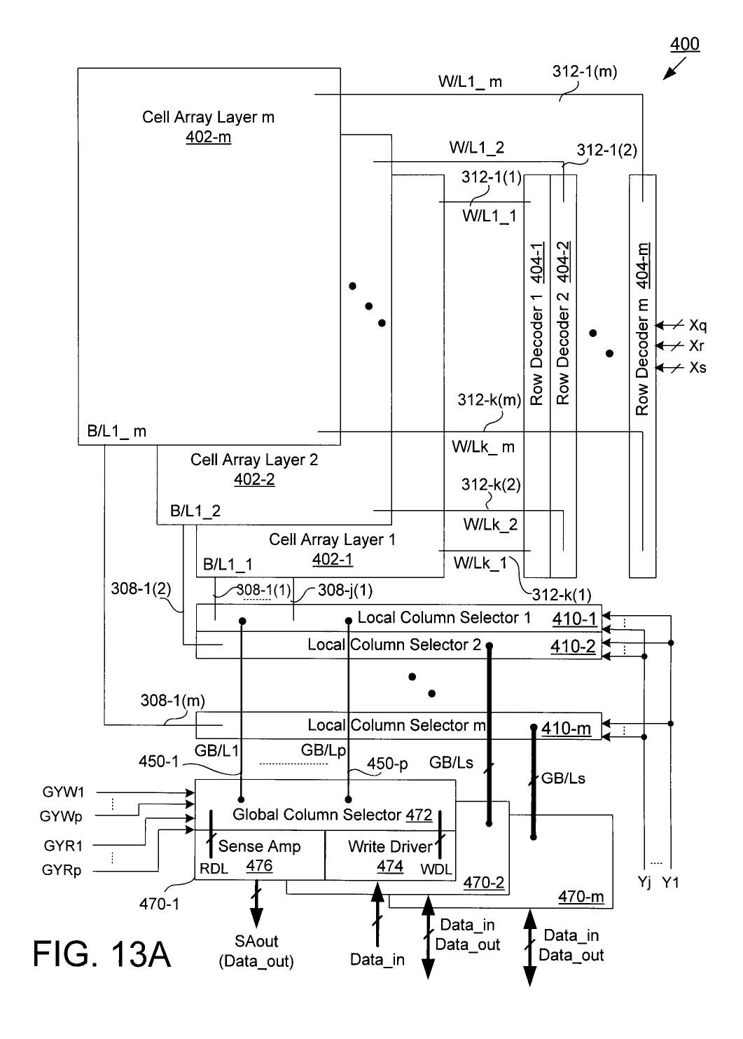

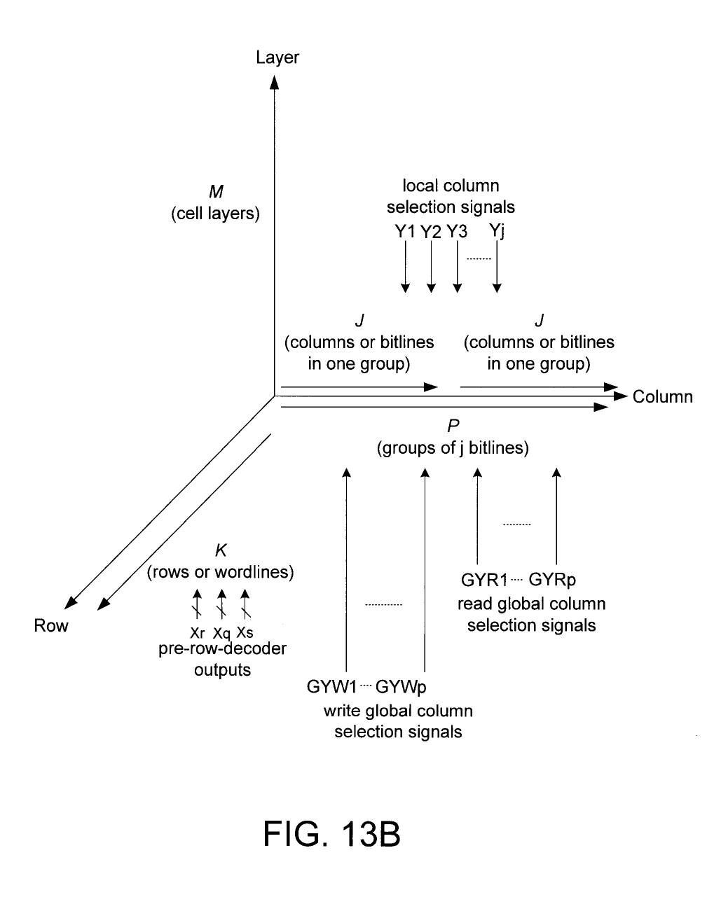

FIG. 13A depicts a three-dimensional memory device architecture according to an embodiment of the present invention. Referring to FIG. 13A, a three-dimensional stacked memory device architecture 400 includes a plurality of PCM cell arrays (cell array layer 1, cell array layer 2, . . . , cell array layer m) formed on a plurality of (m) layers, 402-1, 402-2, . . . , 402-m, respectively, m being an integer greater than one. The PMC cell arrays are on a stack of semiconductor layers. A plurality of PCM cell arrays is formed on each of the layers. The three-dimensional stacked memory device architecture 400 includes a plurality of (m) row decoders 404-1, 404-2, . . . , 404-m and a plurality of (m) local column selectors 410-1, 410-2, . . . , 410-m. For example, m is 4, but it is not limited.

The PCM cell arrays of i-th layer, 402-i, communicates with a corresponding row decoder 404-i and a corresponding local column selector 410-i through a plurality of communication paths, i being 1≦i≦m. The k wordlines “W/L1”-“W/Lk”, 312-1(i)-312-k(i), from the i-th cell array layer 402-i, are connected to the corresponding row decoder 404-i. For example, the wordlines 312-1(1)-312-k(1) from the cell arrays of the first layer 402-1 are connected to the row decoder 404-1. Similarly, the k wordlines 312-1(m)-312-k(m) of the m-th layer 402-m are connected to the row decoder 404-m. The m row decoders 404-1-404-m commonly receive a plurality of pre-row-decoder outputs “Xq”, “Xr” and “Xs” provided by pre-row decoders (not shown).

Each of the first wordlines “W/L1” 312-1(1)-312-1(m) of the m layers 402-1-402-m are connected to the respective one of the row decoders 404-2-404-m. Similarly, each of the k-th wordlines “W/Lk” 312-k(1)-312-k(m) of the m layers 402-1-402-m are connected to the respective one of the row decoders 404-k(1)-404-k(m). The total number of the wordlines is (k×m). A person skilled in the art would understand that the number “m” of semiconductor layers of the stacked memory device architecture is not limited.

In the particular example shown in FIG. 13A, PCM cell array 1 to PCM cell array-p, 302-1-302-p, as shown in FIG. 10 are formed on each of the layers. Referring to FIGS. 10 and 13A, each of the PCM cell arrays 302-1-302p includes j beltlines (B/L1-B/Lj); thus, each layers includes c (=j×p) bitlines, the total number of bitlines of the m layers 402-1-402-m is m×c (=m×j×p).

The p groups of “local” bitlines 308-1-308-j from the cell array layer 402-i of the i-th layer are connected to the corresponding local column selector 410-i. For example, the p groups of j bitlines 308-1-308-j from the cell array layer 402-m of the m-th layer are connected to the local column selector 410-m. The m bitlines “B/L1”, 308-1(1)-308-1(m), from the cell array layers 402-1-402-m of the first to m-th layers are connected to the local column selectors 410-1-404-m. Similarly, the m bitlines “B/Lj” 308-j(1)-308-j(m) from the cell array layers 402-1-402-m of the first to m-th layers are connected to the local column selectors 410-1-410-m.

In the three-dimensional stacked architecture 400, the cell array layers 402-2-402-m are on semiconductor layers formed over the semiconductor layer on which cell array layer 402-1 is formed. The row decoders 404-2-404-m and the corresponding local column selectors 410-2-410-m are formed on the same layer as the row decoder 404-1 and local column selector 410-1. Advantageously, this simplifies the formation of the semiconductor layers used for cell array layers 402-2-402-m, because transistors need not be formed on those layers.

In an embodiment with a PCM cell array based on field-effect transistors or bipolar transistors, rather than diodes, a simpler transistor is formed compared to those required on the layer with the row decoders 404-1-404m and local column selectors 410-1-410-m. The row decoders 404-1-404-m and local column selectors 410-1-410-m may have different speed and leakage requirements compared to those used in a PCM cell array.

The three-dimensional stacked architecture 400 has a plurality of (m) global column operation circuits 470-1, 470-2, . . . , 470-m that communicate with the local column selectors 410-1, 410-2, . . . , 410-m. Each of the m global column operation circuits 470-1, 470-2, . . . , 470-m has the same circuit structure and includes a global column selector 472, a write driver 474 and a sense amplifier 476. The global column selector 472 of each of the global column operation circuits 470-1-470-m is connected to a plurality of (p) global bitlines “GB/Ls” that are further connected to the respective one of the local column selectors 410-1-410-m. For example, the global column selector 472 of the global column operation circuit 470-1 communicates with the corresponding local column selector 410-1 via the p global bitlines 450-1-450-p. Similarly, the global column selector 472 of the global column operation circuit 470-m communicates with the corresponding local column selector 410-m via the p global bitlines GB/Ls.

In each of the m global column operation circuits 470-1, 470-2, . . . , 470-m, the global column selector 472 communicates with the write driver 474 through p global read data lines “RDLs”. The global column selector 472 communicates with the sense amplifier 476 through p global write data lines “WDLs”. The write driver 474 receives input data “Data_in” to be written into memory cells of PCM cell arrays. The sense amplifier 476 provides sense output “SAout” or “Data_out.

FIG. 13B shows memory address control signals for the three-dimensional memory architecture 400 shown in FIG. 13A. Referring to FIGS. 13A and 13B, the plurality of pre-row-decoder outputs “Xq”, “Xr” and “Xs” commonly applied to the m row decoders 404-1-404-m represent the row identification “K”, K being 1≦K≦k. In the particular example, the pre-row-decoder outputs are provided by pre-decoders included in peripheral control circuitry (not shown). The local column selection signals Y1, Y2, . . . , Yj represent a local column identification “J” within one group of the p columns, 1≦J≦j. The global column selector 472 of each of the global column operation circuits 470-1-470-m receives a plurality of (p) write global column selection signals GYW1-GYWp during a write operation and a plurality of (p) read global column selection signals GYR1-GYRp during a read operation. The write global column selection signals GYW1-GYWp (and the read global column selection signals GYR1-GYRp) represent a global column identification “P” of the global columns, 1≦P≦p. The global column identification “P”, the column identification “J”, and the row identification “K” identify or select a memory cell to be accessed (written or read). A layer is identified by a variable M, 1≦M≦m.

Referring to FIGS. 13A and 13B, the write driver 474 receives an input data “Data_in” to be written into the memory cell identified or selected by the identification variables (“J”, “P”, “K”, “M”) in a write operation phase. In a read operation phase, the sense amplifier 476 reads data from the memory cell selected by the identifications and provides sense output “SAout” as the read data. Signals representing the identifications (“J”, “P”, “K”, “M”) are provided by memory control circuitry (not shown). In response to the signals having information on the identifications, peripheral circuitry (the row decoders, the local column selectors, others shown in FIG. 13A) controls operations of the memory device of the three-dimensional PCM architecture.

The write drivers 474, the sense amplifiers 476 and the global column selectors 472 of the m global column operation circuits 470-1, 470-2, . . . , 470-m are formed on the same layer as one of the layers 402-1-402-m. In another embodiment, the row decoders 404-1-404-m and the local column selectors 410-1-410-m are formed on different semiconductor layers from the global column selectors 472, the write drivers 474 and the sense amplifiers 476 of the global column operation circuits. In other embodiments, the row decoders 404-1-404-m, the local column selectors 410-1-410-m, the global column selectors 472, the write drivers 474 and the sense amplifiers 476 are formed on one of the layers; for example, on the last processed layer.

In another embodiment, the row decoders 404-1-404-m, the local column selectors 410-1-410-m, the global column selectors 472, the write drivers 474 and the sense amplifiers 476 are formed on one semiconductor layer, which include no PCM cell array. This advantageously reduces the area required to form the various circuits because the PCM arrays can be sized to be of a similar area and stacked over the circuits. In addition, the layer without the PCM cell array need not include the processing step required to form the phase change material.

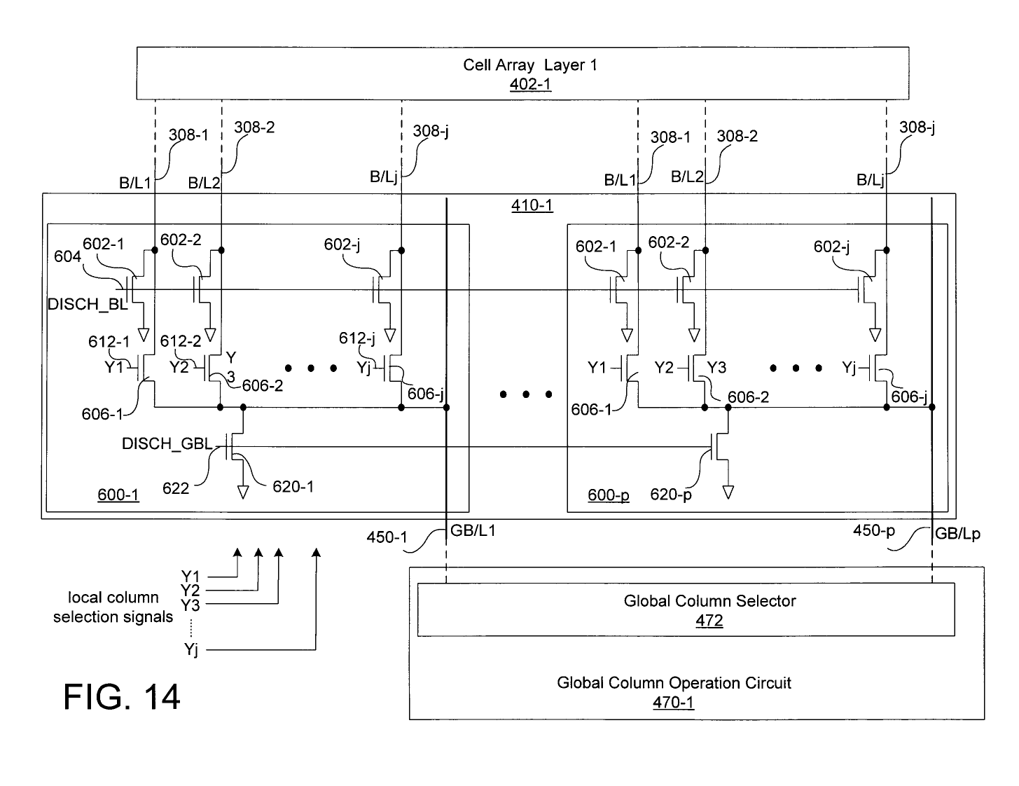

FIG. 14 shows an example of one of the local column selectors 410-1-410-m, for example, the local column selector 410-1, shown in FIG. 13A. Referring to FIG. 14, the local column selector 410-1 has p groups of local column selection circuits 600-1-600-p. The local column selection circuits 600-1-600-p have the same circuit structure. The p groups of j local bitlines 308-1-308-j are connected to the PCM cells formed on the cell array layer 1, 402-1. Each of the column selection circuits 600-1-600-p includes j NMOS transistors 602-1-602-j for performing bitline discharge. The gates of the transistors 602-1-602-j of the p groups of local column selection circuits 600-1-600-p are commonly connected to a bitline discharge signal input 604. Also, each of the column selection circuits 600-1-600-p includes j NMOS transistors 606-1-606-j for performing local column selection, the sources of which are connected to the respective local bitlines 308-1-308-j. The gates of the transistors 606-1-606-j of the p groups are connected to the respective local column select inputs 612-1-612-j. The local column selection signals Y1, Y2, . . . , Yj are commonly fed to the local column select inputs 612-1, 612-2, . . . , 612-j of the p groups to perform local column selection operation.

The p global bitlines “GB/L1”-“GB/Lp” 450-1-450-p are connected to the drains of p NMOS transistors 620-1-620-p, the sources of which are connected to the ground. The gates of the NMOS transistors 620-1-620-p of all column selection circuits 600-1-600-p are commonly connected to a global bit line discharge signal input 622. The drains of the j transistors 606-1-606-j in each of the p groups are commonly connected to the respective global bitline “GB/L1”-“GB/Lp” 450-1-450-p which are connected to the global column selector 472 of the global column operation circuit 470-1.

In response to a common global bitline discharge signal “DISCH_GBL” fed to the global bitline discharge input 622, the NMOS transistors 620-1-620-p perform global bitline discharge in the p local column selection circuits 600-1-600-p. In response to a bitline discharge signal “DISCH_BL” fed to the bitline discharge signal input 604, the transistors 602-1-602-j perform bitline discharge in the p groups of local column selection circuits 600-1-600-p.

Referring to FIGS. 11, 12, 13A, 13B and 14, in the write operation phase, when the cell 304-(2,j) is being written, the bitline discharge signal “DISCH_BL” fed to the input 604 and the common global bitline discharge signal “DISCH_GBL” fed to the input 622 are “low” to deactivate the respective discharge paths (which include the beltlines and global bitlines). In response to the local column selection signals Y1, Y2, . . . , Yj fed to the local column select inputs 612-1, 612-2, . . . , 612-j, selection of bitline is performed.

In a case where only Yj is “high”, the gates of the transistors 606-1, 606-2, . . . in each of the local column selection circuits 600-1-600-p are “low”, so that the column select transistors 606-1, 606-2, . . . , are deactivated and bitlines 308-1, 308-2, . . . are floating. The gates of the transistor 606-j of the local column selection circuits 600-1-600-p are held “high” and the column select transistors 606-j are activated. As a result, each of the global bitlines 450-1-450-p is connected to the local bitline 308-j that is associated with the memory cell 304-(2,j) to be written, through the activated transistor 606-j. Similarly, different logic status of the local column selection signals Y1, Y2, . . . , Yj causes a different bitline to be selected to select or identify a memory cell to be written.

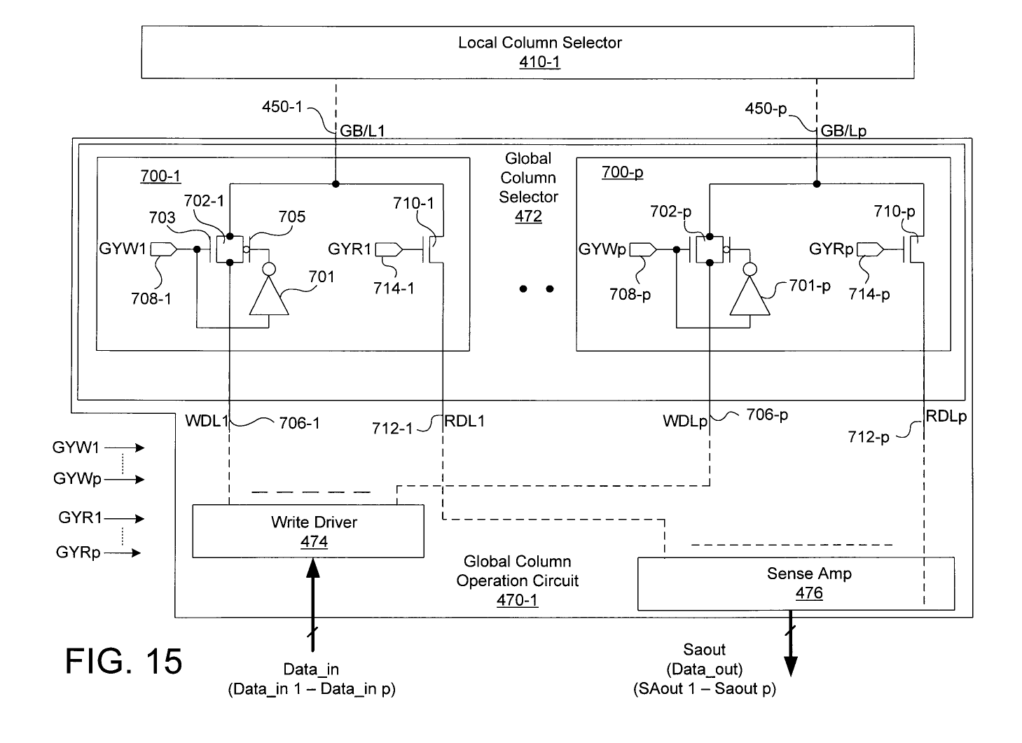

FIG. 15 shows an example of one of the global column selectors as shown in FIG. 13A. Referring to FIG. 15, one global column selector (e.g., the global column selector 472 of the global column operation circuits 470-1) includes p global column selection circuits 700-1-700-p. Each of the p global column selection circuits 700-1-700-p operates for a respective one of global bit lines 450-1, 450-2, . . . , 450-p (“GB/L1”-“GB/Lp”) that are connected to the local column selector 410-1. Each of the p global column selection circuits 700-1-700-p includes a full CMOS transmission gate, an inverter and an NMOS transistor.

In the global column selection circuit 700-1, a transmission gate 702-1 is formed by an NMOS transistor 703 and a PMOS transistor 705 and is located between the global bitline “GB/LP” 450-1 and a global write data line “WDL1” 706-1. The gate of the NMOS transistor 703 is connected to a write global column select input 708-1 that is connected via the inverter 701-1 to the gate of PMOS transistor 705. The source and gate of an NMOS transistor 710-1 are connected to the global bitline “GB/L1” 450-1 and a read global column select input 714-1, respectively. Similarly, in the global column selection circuit 700-p, a transmission gate 702-p is formed by an NMOS transistor and a PMOS transistor and is located between the global bitline “GB/Lp” 450-p and a global write data line “WDLp” 706-p. A write global column select input 708-p is connected to the NMOS transistor of the transmission gate 702-p and through an inverter 701-p to the PMOS transistor of the transmission gate 702-p. The source and gate of an NMOS transistor 710-p are connected to the global bitline “GB/Lp” 450-p and a read global column select input 714-p, respectively. Each of the other global column selection circuits has the same structure as that of the global column selection circuit 700-1.

The transmission gates 702-1-702-p are connected to the global write data lines “WDL1”-“WDLp” 706-1-706-p, respectively, which are connected to the write driver 474 of the global column operation circuit 470-1. The drains of the transistors 710-1-710-p are connected to the p global read data lines “RDL1”-“RDLp” 712-1-712-p, respectively, which are connected to the sense amplifier 476 of the global column operation circuit 470-1.

In the data write operation, the write global column selection signals GYW1-GYWp are provided to the respective inputs 708-1-708-p of the global column selection circuits 700-1-700-p to control of operations of the transfer gates 702-1-702-p for data writing. In the data read operation, the read global column selection signals GYR1-GYRp are provided to the respective inputs 714-1-714-p of the global column selection circuits 700-1-700-p to control the operations of the transistors of 710-1-710-p for data reading.

The global column selector 472 of the global column operation circuit is used to select one of the p groups of local column decoders 600-1-600-p shown in FIG. 14. The global column selector 472 performs operation of selecting a global bitline for write data from the global write data line, for example, “WDL1” 706-1, or of selecting a global bitline for read data to the global read data line, for example, “RDL1” 712-1. While the write global column selection signal GYW1 is “high”, the global write data line “WDL1” 706-1 is connected to the global bit line “GB/L1” 450-1 through a complementary pair of PMOS and NMOS transistors (the full CMOS transmission gate 702-1), so that a full supply voltage is passed to the memory cell, for example, 304-(2,j) of FIG. 12. This ensures a wider margin or separation between the RESET and SET states in the memory cell to which data is written. The read path to the global read data line, for example, “RDL1”, requires a single ended device (e.g., the NMOS transistor without a PMOS transistor), because the read signal can be sensed without the full supply voltage differential caused by reading the two programmed states (i.e., the set state “1” and the reset state “0”). While the read global column selection signal GYR1 is “high”, the NMOS transistor 710-1 is turned on and the global bit line “GB/L1” 450-1 is connected to the global read data line “RDL1” 710-1 through the on transistor 710-1.

As shown in FIG. 15, the p global column selection circuits 700-1-700-p are connected to the respective global write data lines WDL1-WDLp and the respective global read data lines RDL1-RDLp. Therefore, the p pairs of the write and read data lines are connected to one global column selection circuit 472. The write driver 474 receives the input data “Data_in” that comprises p input data: “Data_in 1”-“Data_in p” to be written into memory cells. The sense amplifier 476 provides sense output “SAout” or “Data_out that comprises p data outputs:“SAout 1”-“SAout p” as data read from memory cells.

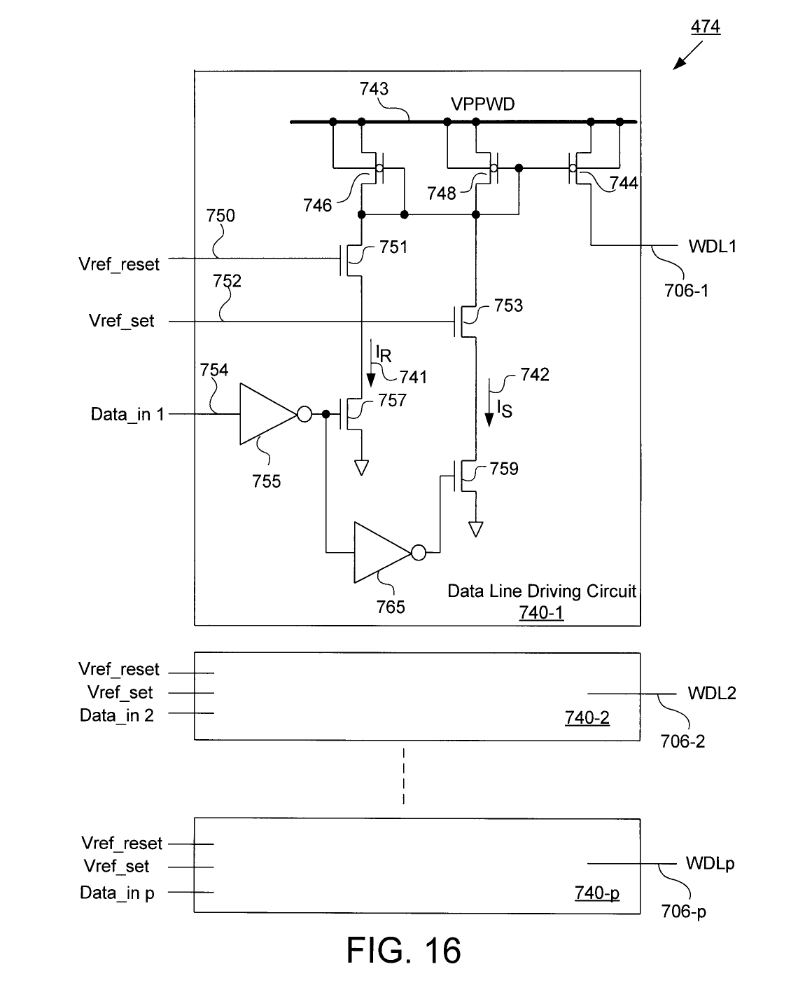

FIG. 16 shows an example of one of the write drivers (e.g., the write driver 474 of the global column operation circuits 470-1) shown in FIG. 13A. Referring to FIG. 16, the write driver 474 includes p data line driving circuits 740-1-740-p. In one data line driving circuit, for example, 740-1, one PMOS transistor 746 and two NMOS transistors 751 and 757 are connected in-series between a voltage line 743 of VPPWD and the ground. VPPWD is, for example, VDD+1 volt. Similarly, one PMOS transistor 748 and two NMOS transistors 753 and 759 are connected in-series between the voltage line 743 and the ground. The gates and drains of the PMOS transistors 746 and 748 are coupled and connected to the gate of another PMOS transistor 744, the source and drain of which are connected to the voltage line 743 and the global write data line, for example, “WDL-1” 706-1, respectively. The gates of the NMOS transistors 751 and 753 are connected to a reset reference signal input 750 and a set reference signal input 752, respectively. A data input 754 is connected via an inverter 755 to the gate of the NMOS transistor 757 and further connected via another inverter 765 to the gate of the NMOS transistor 759. Each of the other data line driving circuits 740-2-740-p has the same circuit structure as that of the data line driving circuit 740-1. The data line driving circuits 740-1-740-p are connected to the global write data lines “WDL1”-“WDLp” 706-1-706-p, respectively, which are in turn connected to the corresponding global column selector 472 as shown in FIG. 15.

Referring to FIGS. 13A, 13B and 14-16, a reset reference voltage “Vref_reset” is fed to the reset reference signal input 750 when data “0” is written. A set reference voltage “Vref_set” is fed to the set reference signal input 752 when data “1” is written. Data input signal representing the input data “Data_in” (“Data_in 1”-“Data_in p”) is fed to the data input 754 of the respective one of the p data line driving circuits 740-740-p). In one data line driving circuit, in response to the data input signal “Data_in” and the reset reference voltage “Vref_reset” current “I_{R}” 741 flows through the NMOS transistors 751 and 757. In response to the data input signal “Data_in” and the set reference voltage “Vref_set”, current “I_{S}” 742 flows through the NMOS transistors 753 and 759. The “low” state of the “Data_in” signal turns on the NMOS transistor 757. The “high” state of the “Data_in” signal turns on the other NMOS transistor 759.

A current mirror formed by PMOS transistors 746 (and 748) and 744 mirrors the current I_{R} 741 to the global write data line “WDL” 706-1 during the write “reset” operation. A current mirror formed by the PMOS transistors 748 (and 746) and 744 mirrors the current I_{S} 742 to the global write data line WDL 706-1 during the write “set” operation. The current I_{R} 741 or I_{S} from the global write data line flows through the selected global bitline. The current further flows through the selected local bitline and the selected cell (see FIG. 11).

The write driver 474 provides proper current to the global write data line during the write operation of data “1” and “0”. For example, the data line driving circuit 740-1 performs the set operation by the set reference voltage Vref_set. When the set reference voltage Vref_set is “high”, the transistor 753 is turned on. While Data_in 1 is “high” (logic ‘1’), the transistor 759 is turned on. While the transistors 753 and 759 are conductive, the current I_{S} 742 flows therethrough. The reset operation is performed by the “low (logic ‘0’) in Data_in 1 while the transistor 751 is enabled to be turned on in response to the “high” state of the reset reference voltage Vref_reset. While the transistors 751 and 757 are conductive, the current I_{S} 742 flows therethrough. Mirrored currents of the currents “I_{R}” 741 and “I_{S}” 742 flow through the global write data line WDL 706-1. The transistors 751 and 753 have different sizes such that the current to achieve the logic ‘0’ is different from that of the logic ‘1’. In the particular example, the resultant I_Set and I_Reset are, for example, about 0.2 mA and 0.6 mA, respectively. It should, however, be clearly understood that different values can be used depending upon cell implementation. The pulse durations of the currents I_Set and I_Reset are controlled by the widths of the voltages Vref_set and Vref_reset, respectively. In another example, a different pulse duration can be produced for the low state and the high state by controlling the pulse widths of Vref_Set and Vref_Reset. The voltages Vref_set and Vref_reset function as data write enabling signals for data “1” and data “0”, respectively. In another example, a different pulse duration can be produced for the low state and the high state by controlling the pulse widths of Vref_Set and Vref_Reset.

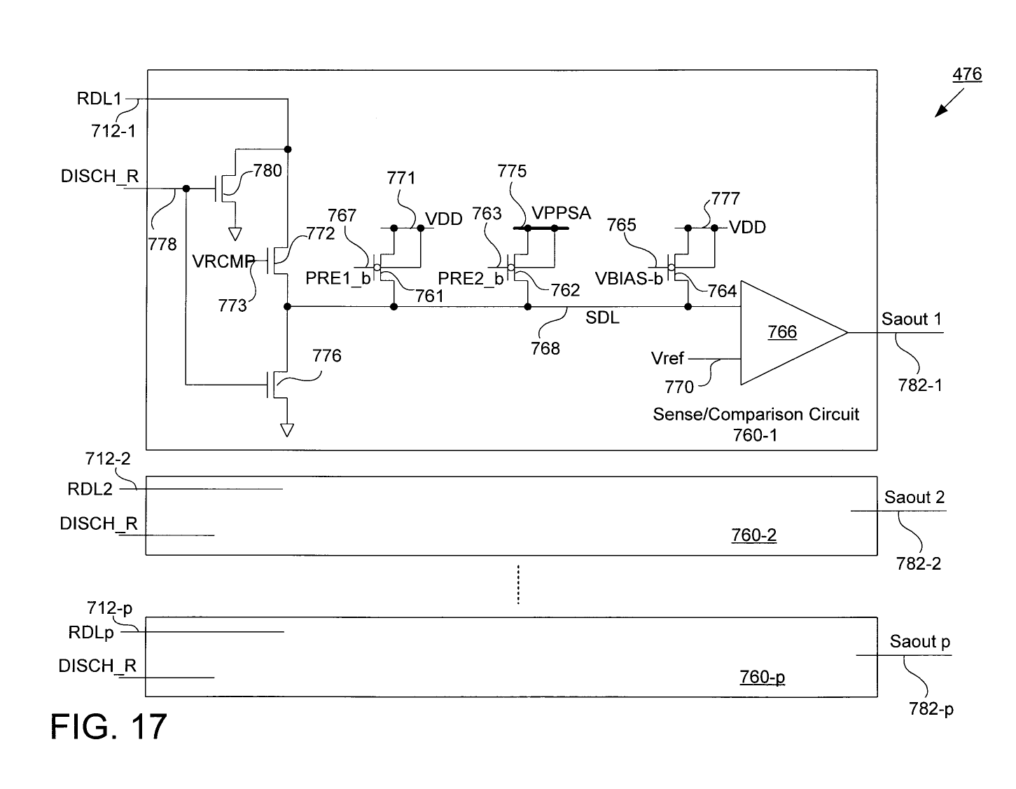

FIG. 17 shows an example of one of the sense amplifiers (e.g., the sense amplifier 476 of the global column operation circuits 470-1) shown in FIG. 13A. Referring to FIG. 17, the sense amplifier 476 has a plurality of (p) sense/comparison circuits 760-1-760-p. In one sense/comparison circuits, for example the sense/comparison circuit 760-1, the global read data line “RDL1” 712-1 is connected to the drain of an NMOS discharge transistors 780 and the source of an NMOS voltage clamp transistor 772. The drain of the transistor 772 is connected to the drain of another NMOS discharge transistor 776, the source of which is connected to the ground. The gate of the transistor 772 is connected to a clamping signal input 773 to which a clamping voltage VRCMP is fed. The gates of the discharge transistors 780 and 776 are connected to a discharge signal input 778. The drains of the transistors 772 and 776 are connected to a sensing data line “SDL” 768.

The sense/comparison circuit 760-1 includes two PMOS bitline precharge transistors 761 and 762. The source and gate of the transistor 761 are connected to a voltage line 771 and a precharge signal input 767, respectively. The source and gate of the transistor 762 are connected to a voltage line 775 and another precharge signal input 763, respectively. The sense/comparison circuit 760-1 includes another PMOS transistor 764, the source and gate of which are connected to a voltage line 777 and a bias signal input 765, respectively. The voltage lines 771 and 775 are connected to voltage sources (not shown) of VDD and VPPSA, respectively. VDD is for example 1.8 volts. VPPSA is typically greater than VDD, for example, VDD+2 volts. The drains of the three transistors 761, 762 and 764 are connected to the sensing data line “SDL” 768. A differential voltage amplifier (comparator) 766 has two inputs connected to the sensing data line “SDL” 768 and a reference input 770 to which a reference voltage Vref is fed.

Referring to FIGS. 13A, 13B, 14, 15 and 17, the p sense/comparison circuits 760-1-760-p are connected to the global column selector 472 (the global column selection circuits 700-1-700-p) through the global read data lines “RDL1”-“RDL-p” 712-1-712-p. The sense amplifier 476 reads data from bitlines in the PCM cells of the cell array layer (e.g., the array layer 402-1) shown in FIG. 13A). The bitlines in the memory array are selected by the local column selector 410-1 and the local column selectors 410-1, 410-2, . . . , 410-m are selected by the global column selector 472. The data passes from the PCM cell to the sense amplifier 476 on the selected one of the global read data lines “RDLs”.

A discharge voltage “DISCH_R” is fed to the discharge signal input 778. While the “DISCH_R” voltage is “high”, the discharge transistors 780 and 776 are on and the global read data line “RDL1” 712-1 and the sensing data line “SDL” 768 discharge in preparation for a read operation. Precharge voltages “PRE1_b” and “PRE2_b” are fed to the precharge signal inputs 767 and 763, respectively. The two precharge transistors 761 and 762 provide a more gradual precharge rate on the bitlines. Advantageously, the two slope precharging approach reduces the burden on the charge pump used to supply the VPPSA voltage. VPPSA is boosted from VDD by a charge pump (not shown). In one embodiment, VPPSA is VDD+2V. Charge pumps have limited current sourcing ability for a given area. The two stage precharge scheme is achieved by the two transistors 761 and 762. The first stage precharge is performed in response to PRE1_b to raise the sensing data line “SDL” 768 from 0V to VDD by sourcing current directly from VDD. Then, the second stage precharge is performed in response to PRE2_b, which charges the sensing data line “SDL” 768 from VDD of the voltage line 771 to VPPSA (of the voltage line 775) using current supplied by the VPPSA charge pump. By precharging the sensing data line “SDL” 768 to VPPSA, adequate read voltage margin for diode based PCM cells is ensured.

A bias voltage “VBIAS_b” (e.g., VDD) is fed to the bias signal input 765. The bias transistor 764 provides a load current equal to the current sunk by the selected memory cell 304-(2,j) (of FIG. 11), excluding parasitic currents and converts the current drawn from the selected memory cell into a voltage on the sensing data line “SDL” 768. The amplifier 766 then compares the developed voltage on the sensing data line “SDL” 768 with the reference voltage “Vref” fed to the reference input 770. In the case where the voltage level on the sensing data line “SDL” 768 exceeds the reference voltage Vref, a sense amplifier output “SAout 1” at a sense output 782-1 of the amplifier 766 is driven to “high”. The SAout is the data out “Data_out” representing read data.

Referring to FIGS. 4A, 4B, 11 and 17, when the memory cell 304-(2,j) is programmed to the reset state, the amorphous material (the programmable volume) 132 is developed in the chalcogenide compound 126. The amorphous state causes a higher resistance between the first electrode 124 and the second electrode 128. A current flowing through the higher resistance compound 126 results in a larger voltage drop thereacross. Consequently, a greater voltage drop is developed across the memory cell 304-(2,j) and a greater voltage is sensed at the sensing data line “SDL” 768. The higher resistance of the chalcogenide compound 126 (the phase change layer) corresponds to the RESET state “Data “0” shown in FIG. 4A. The resistance is greater than the crystalline that corresponds to the SET state “Data 1” (FIG. 4A).

Each of the other sense/comparison circuits 760-2-760-p has the same circuit structure and performs the same operation as those of the sense/comparison circuit 760-1. The other sense/comparison circuits 760-2-760-p receive signals representing read data through the global read data lines “RDL2”-“RDL-p” 712-2-712-p, respectively. The sense/comparison circuits 760-2-760-p provides the SAout 2-SAout p as the data out “Data_out” from the sense outputs 782-2-782-p, respectively. The p data outputs “SAout 1”-“SAout p” form the sense output “SAout” or “Data_out.

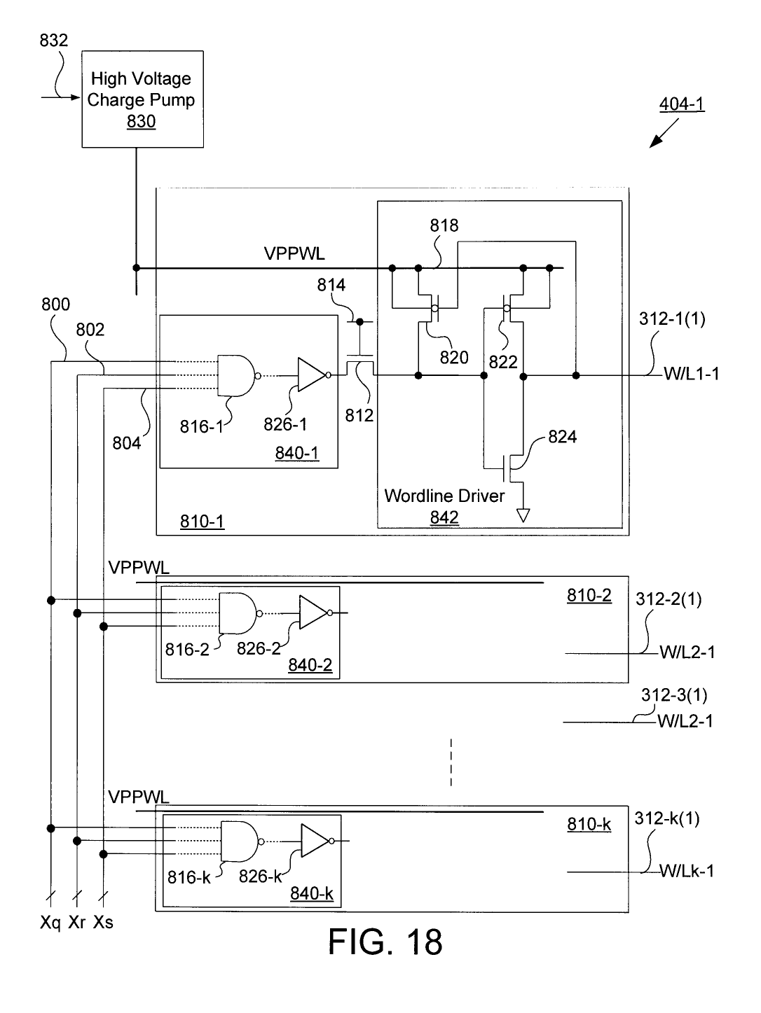

FIG. 18 shows an example of one of the row decoders (e.g., the row decoder 404-1) shown in FIG. 13A. The row decoder 404-1 has a plurality of (k) decoding circuits 810-1-810-k that are connected through the wordlines to the PCM cell memories of the cell array layer 402-1 shown in FIG. 13A. The particular decoding circuit shown in FIG. 18 includes decoding logic circuitry for decoding address input signals in response to pre-row-decoder outputs and a wordline driver for providing “selected” or “non-selected” voltage to the wordline in response to the decoded address signal. The decoding logic circuitry includes a combination of logic gates. In FIG. 18, only one NAND gate and one inverter are shown for representing decoding logic circuitry. The wordline driver includes MOS transistor based driving circuitry.

Referring to FIGS. 13A, 13B and 18, in one of the decoding circuit 810-1 has three sets of pre-decoded signal inputs 800, 802 and 804 for receiving the pre-row-decoder outputs “Xq”, “Xr” and “Xs”, respectively. Each of the three pre-row-decoder outputs Xq, Xr and Xs includes address information (“1”-“8”) and thus, Xq, Xr and Xs represent addresses of (2²)²: “001”-“512”. The decoding circuit 810-1 has decoding logic circuitry 840-1 including a NAND gate 816-1 and an inverter 826-1 connected to output of the NAND gate 816-1. The decoding logic circuitry 840-1 has inputs that are connected to the pre-decoded signal inputs 800, 802 and 804. The decoding circuit 810-1 has a wordline driver 842 including a pull-up PMOS transistor 820 and a complementary circuit of PMOS transistor 822 and an NMOS transistor 824. The output of the inverter 826-1 is connected through a clamping NMOS transistor 812 to the drain of PMOS transistor 820 and the gates of PMOS transistor 822, an NMOS transistor 824. The sources of the PMOS transistors 820 and 822 are connected to a voltage line 818 to which voltage VPPWL is provided. The drains of the PMOS transistor 822 and the NMOS transistor 824 are commonly connected to the wordline “W/L1-1” 312-1(1) and the gate of the PMOS transistor 820.

Each of the decoding circuits 810-2-810-k has similar circuit structure as that of the decoding circuit 810-1. The decoding circuit 810-2 has decoding logic circuitry 840-2 including NAND gate 816-2 and an inverter 826-2. Similarly, the decoding circuit 810-k has decoding logic circuitry 840-k and an inverter 826-k. Each of the decoding circuits 810-2-810-k has a wordline driver. The decoding circuits 810-2-810-k commonly receive the pre-row-decoder outputs “Xq”, “Xr” and “Xs”. The decoding circuits 810-2-810-k are connected to the wordlines “W/L1”-“W/Lk” 312-2(1)-312-k(1), respectively.

The row decoder 404-1 is enabled by the pre-row-decoder outputs “Xq”, “Xr” and “Xs”. In the case where the wordline W/L1 is to be selected, the output of the NAND gate 816-1 is “low” and the inverter 826-1 outputs “high”. The transistor 824 is on and the wordline W/L1-1, 312-1(1) is pulled down to “low” or “0”. In the case where the wordline W/L1 is to be unselected, the output of the NAND gate 816-1 is “high” and the inverter 826-1 outputs “low”. The transistor 822 is on and the wordline “W/L1-1” 312-1(1) is pulled up to “high (VPPWL)”. Therefore, “0V” or “VPPWL” is provided to the wordline in response to the address decoding.

The decoding output of the row decoder 404-1 is provided to the corresponding wordline. The decoding output at the wordline is set to 0V when the memory cell connected to the wordline is selected. The decoding output is set to VPPWL at the wordline to which non-selected memory cell is connected. At the time of a wordline being unselected, the applied voltage to the selected wordline is VPPWL of the voltage line 818. The applied voltage is VDD+2V during the write operation, regardless whether the set write or the read write, as shown in FIG. 11. The applied voltage is VDD+1V during the read operation as shown in FIG. 12. Such voltages are described above in Table 2.

The voltages of VDD+2V and VDD+1V are supplied as VPPWL by a high voltage charge pump 830 in response to an operation phase signal 832 provided by a memory controller (not shown). The operation phase signal 832 indicates a write operation phase or a read operation phase. Since circuitry of the high voltage charge pump 830 is known, for example, a charge pump, its details are omitted.

In the case where the wordline “W/L2” 312-2 is selected as shown in FIGS. 11 and 12, the decoding circuit 810-2 in the row decoder 404-1 connected to the wordline “W/L2-1” 312-2(1) outputs the decoded output (0V). The decoding circuits connected to the non-selected wordlines output the voltage of VPPWL. The voltage VPPWL is VDD+2V or VDD+1V provided by the high voltage charge pump 830 in accordance with the operation phase signal 832.

The clamping transistor 812 is controlled by voltage provided to a line 814 to prevent the voltage VPPWL at the voltage line 818 from sourcing excessive voltage back to the decoding logic circuitry 840-1. The pull-up transistor 820 is activated when “W/L1-1” 312-1 is “low”. This ensures that the “low” level at “W/L1” 312-1 used to select a memory cell 304-(2,j) on a row to be read (e.g., 312-2 in FIG. 12) or the memory cell 304-(2,j) on a row to be written (e.g., the wordline 312-2 in FIG. 11) will be more immune to noise coupling from adjacent wordlines (e.g., the wordlines “W/L1-1” 312-1(1) and “W/L2-1” 312-3(1)).

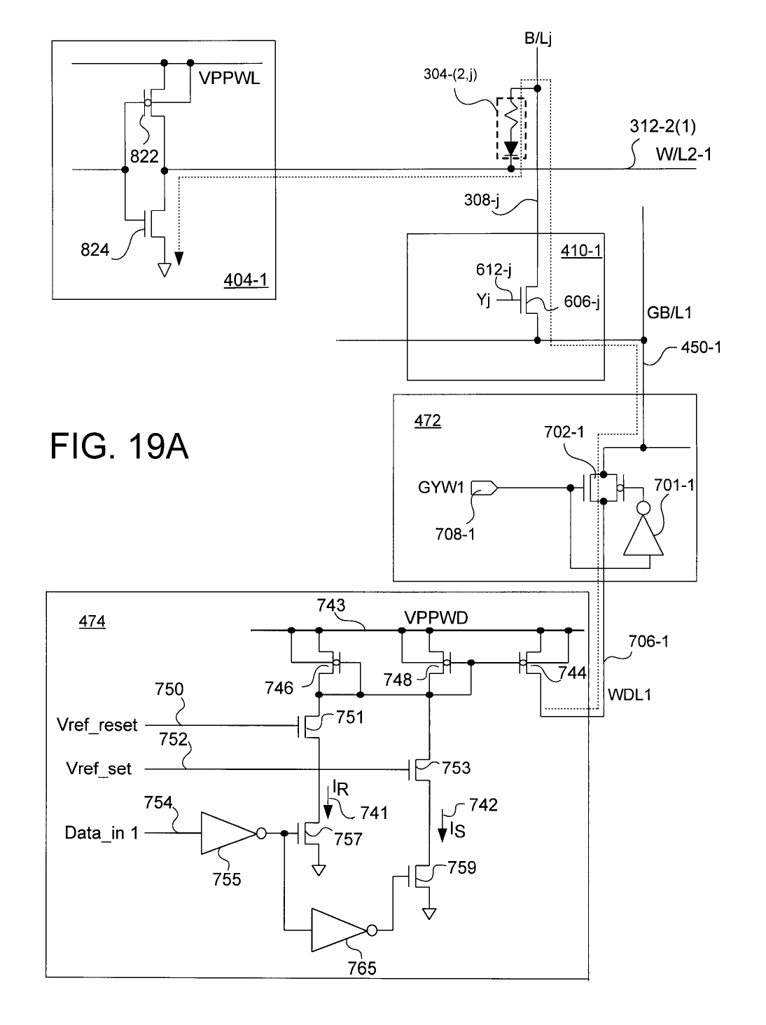

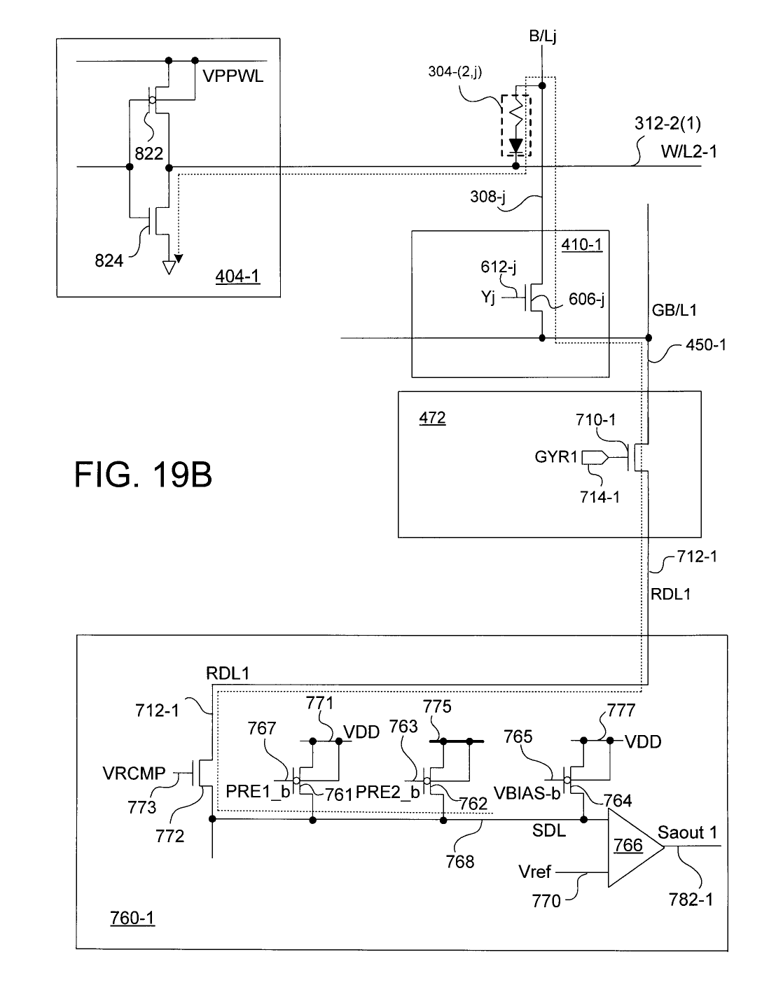

FIG. 19A shows a circuit performing the write operation of the three-dimensional memory according to an embodiment of the invention. It is assumed that a memory 304-(K,J) to be written is the memory cell 304-(2,j) in the first group of the PCM cell array 1, 302-1, of the cell array layer 1, 402-1. The variables to identify the cell are:

(i) Identification of layer M is “1”;

(ii) Identification of local column J is “j”;

(iii) Identification of global column P is “1”; and

(iv) Identification of row K is “2”.

Thus, the local column selection signal Yj is “high”. The write global column selection signal GYW1 is “high”. The row address identified by the pre-row-decoder outputs “Xq”, “Xr” and “Xs” is “002”. A circuit performing the write operation of the three-dimensional memory is formed as shown in FIG. 19A.

Referring to FIGS. 10, 11, 13A, 13B, 14, 15, 16, 18 and 19A, the global bitline “GB/L1” 450-1, the local bitline “B/Lj” 308-j, and the wordline “W/L2-1” 312-2(1) are selected by the variables of identification (M, J, P, K). The selections cause that transmission gate 702-1 of the global column selector 472 and the NMOS column select transistor 606-j of the local column selector 410-1 are turned on and conductive. The wordline driver 842 of the row decoder 404-1 provides 0V to the selected wordline “W/L2-1” 312-2(1).

The PMOS transistor 744 of the write driver 474 to which VPPWD is supplied provides the mirror current of I_{S} or I_{R} to the global write data line “WDL1” 706-1 in response to the input data “Data_in 1” of data “1” or “0”. The current flows through the conductive transmission gate 702-1, the global bitline “GB/L1” 450-1, the conductive column select transistor 606-j, the local bitline “B/L1” 308-j, the selected memory cell 304-(2,j) and the selected wordline “W/L2-1” 312-2(1). The mirror current of I_{S} and I_{R} result in the current I_Set and I_Reset, respectively, as shown in FIG. 11. The currents cause different voltages to be developed across the resistor of the memory cell 304-(2,j) to store data “1” or “0”.

FIG. 19B shows a circuit performing a read operation of the three-dimensional memory according to an embodiment of the invention. It is assumed that a memory 304-(K,J) from which data is read is the memory cell 304-(2,j) in the first group of the PCM cell array 1, 302-1, of the cell array layer 1, 402-1. Thus, the local column selection signal Yj is “high”. The read global column selection signal GYR1 is “high”. The row address identified by the pre-row-decoder outputs “Xq”, “Xr” and “Xs” is “002”. A circuit performing the read operation of the three-dimensional memory is formed as shown in FIG. 19B.

Referring to FIGS. 10, 12, 13A, 13B, 14, 15, 16, 18 and 19B, the global bitline “GB/L1” 450-1, the local bitline “B/Lj” 308-j, and the wordline “W/L2-1” 312-2(1) are selected. The selections cause that the NMOS transistor 710-1 of the global column selector 472, the NMOS column select transistor 606-j of the local column selector 410-1 are turned on and conductive.

The NMOS voltage clamp transistor 772 is turned on by the clamping voltage VRCMP and a two-step precharge operation is performed by the two precharge PMOS transistors 761 and 762 with the precharge signals PRE1_b 761 and PRE2_b 763, respectively. Thereafter, the PMOS transistor 764 is turned on in response to the bias voltage “VBIAS_b” (of 0V) and the voltage VDD of the voltage line 777 is provided to the SDR 768 through the on transistor 764 and causes a current to flow therein. The current further flows through the on transistor 772, the global read data line “RDL1” 712-1, the on NMOS transistor 710-1 of the global column selector 472, the global bitline “BL/L1” 450-1, the on NMOS column select transistor 606-j of the local column selector 410-1. It results in that the current I_Read flows the local bitline “B/Lj” 308-j, the selected memory cell 304-(2,j) and the selected wordline “W/L2-1” 312-2(1) as shown in FIG. 12. The resistance of the resistor in the memory cell 304-(2,j) is different between the conditions wherein the data “1” and “0” have been written. Different voltages are developed between the data “1” and “0” conditions in the SDR 768 connected in series with the resistor. Comparing the developed voltage with the reference voltage Vref, the amplifier 766 provides the sense out “SAout 1” representing data “1” or “0”.

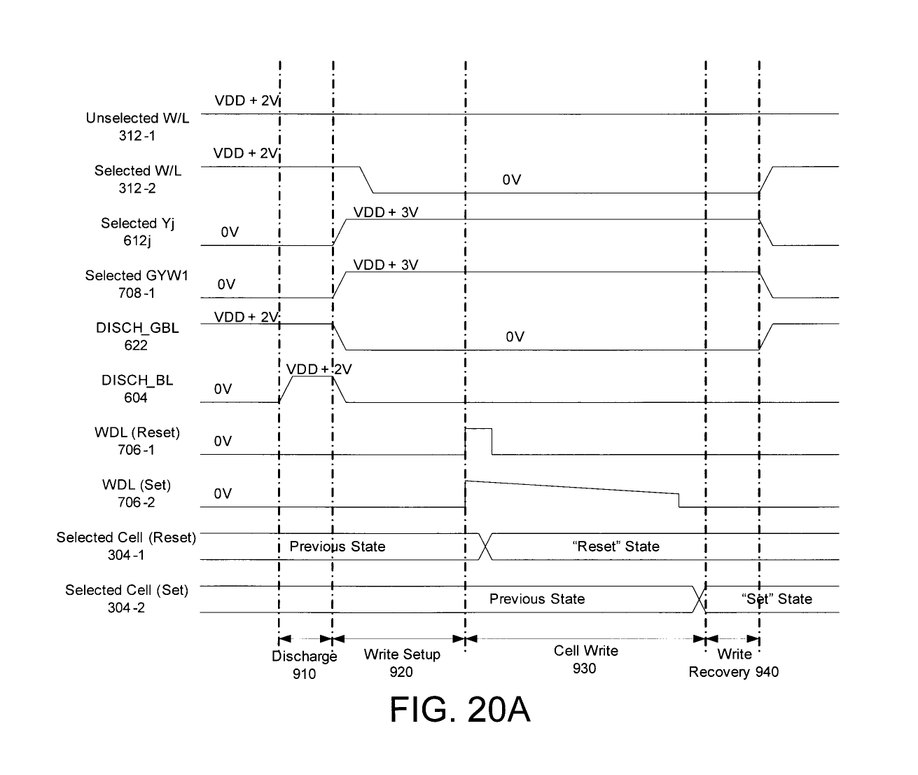

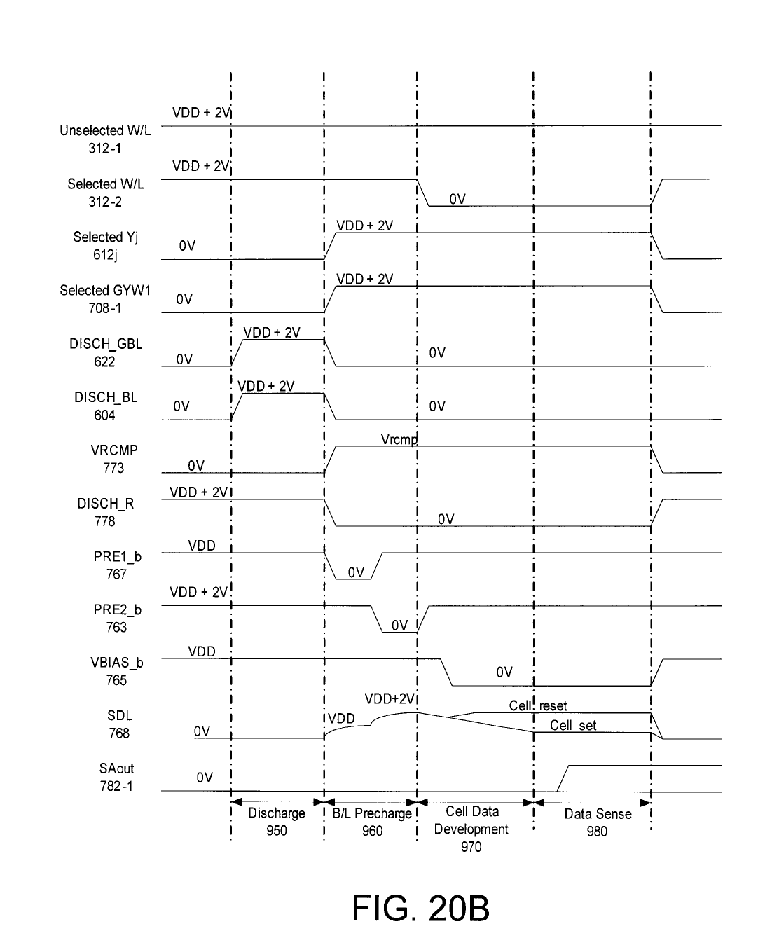

FIG. 20A shows write operation of the three-dimensional memory according to an embodiment of the invention. The write operation includes four phases, namely “Discharge” 910, “Write Setup” 920, “Cell Write” 930 and “Write Recovery” 940.

Referring to the figures, during Discharge phase 910, the local bitlines B/L1-B/Lj and the global bitlines GB/L1-GB/Lp are discharged to 0V. This is accomplished by raising the bitline discharge signal “DISCH_BL” fed to the bitline discharge signal input 604 and the common global bitline discharge signal “DISCH_GBL” fed to the global bit line discharge signal input 622 to VDD+2V. Raising DISCH_BL and DISCH_GBL to a voltage greater than VDD provides more drive current to discharge the bitlines and the global bitlines, respectively. In another embodiment, the DISCH_BL and DISCH_GBL are only raised to VDD and the Discharge phase 910 is extended for longer discharge time. During the Discharge phase 910, the wordlines (e.g., the wordlines 312-1 and 312-3) are deselected by applying VDD+2V.

Although the wordlines need to be raised to approximately one diode threshold above the bitline (e.g., the bitline 308-j) potential to prevent the memory cells from conducting, raising the wordlines to VDD+2V ensures that the memory cells will not conduct current while the bitlines are discharging.

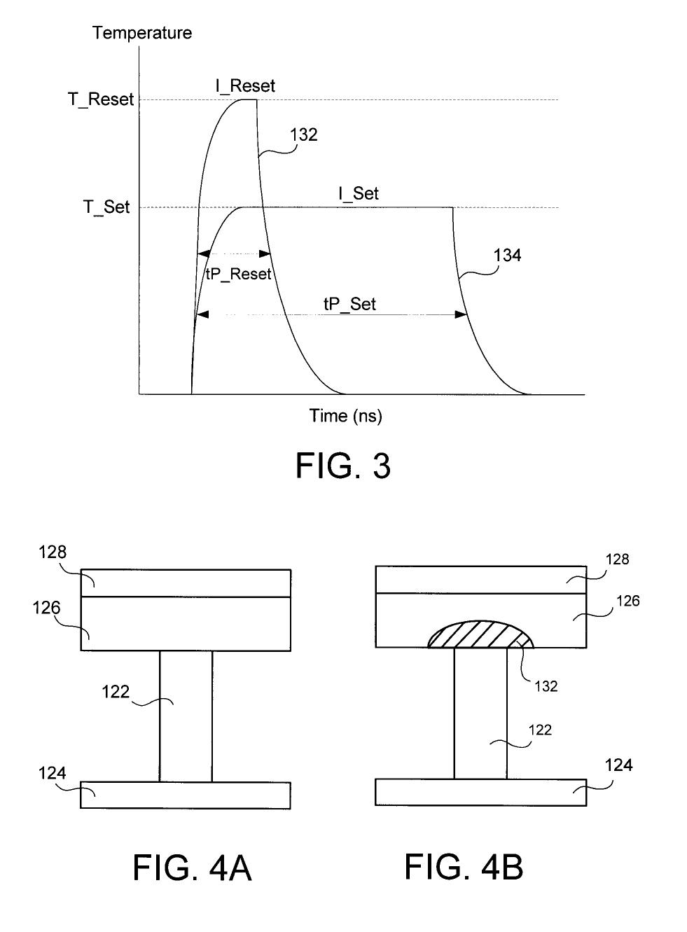

During the Write Setup phase 920, the local bitlines and the global bitlines are allowed to “float” by deactivating the bitline discharge signal “DISCH_BL” and the common global bitline discharge signal “DISCH_GBL”. A floating bitline means the bitline potential is not driven by a low impedance source (e.g., a driver) but can significantly maintain the previously potential with the parasitic capacitance of the bitline. The global write data line WDL 706-1 shown in FIG. 16 is provided to the bitline 308-j connected to the memory cell 304-(2,j) intended to be written to, by activating the local column selection signal Yj and the write global column selection signal GYW1. In addition, the selected wordline 312-2 is biased to 0V to allow memory cell 304-(2,j) to be written. During the Cell Write phase 930, the cell is written to the reset state by fast quenching or to the set state by slow quenching, respectively. The write driver provides the write current in accordance with the input data shown in FIG. 16. For example, in response to “Data_in 1” being “0”, to write the reset state, a narrower pulse (e.g., the pulse 132 as shown FIG. 20A in FIG. 3) is provided to the global write data line WDL 706-1 in FIG. 20A. Similarly, in response to “Data_in 2” being “1”, to write the set state, a wider pulse (e.g., the pulse 134 as shown in FIG. 3) is provided to the global write data line 706-2 in FIG. 20A.

During the Write Recovery phase 940, the chalcogenide compound 248 in FIGS. 4A and 4B is given additional time to crystallize and cool. Following the Write Recover phase 940, the selected wordline 312-2 and the global bitline discharge signal “DISCH_GBL return to VDD+2V. The local column selection signal Yj and the global column selection signal GYW1 are turned off.

FIG. 20B shows read operation of the three-dimensional memory according to an embodiment of the invention. The read operation includes four phase: “Discharge” 950, “B/L Precharge” 960, “Cell Data Development” 970 and “Data Sense” 980.

Referring to the figures, during the Discharge phase 950, the local bitlines and the global bitlines are discharged by the bitline discharge signal “DISCH_BL” and the common global bitline discharge signal “DISCH_GBL”, similar to the write operation. In addition, the global read data line “RDL” 712 and the sensing data line “SDL” 768 are discharged by applying VDD+2V to the discharge voltage DISCH_R.

During the bitline-precharge phase 960, the transistors of the local and global column selectors are turned on by the selected column selection signal Yj 612-j and the global column select line GYW1 708-1, respectively. The clamping voltage VRCMP applied to the clamping signal input 773 is set to a voltage level of “Vrcmp”, which will cause the clamping transistor 772 to limit the voltage that can be passed from the global read data line RDL 712 to the sensing data line “SDL” 768, so that the amplifier 766 is prevented from saturating and limiting recovery time. In one embodiment, Vrcmp is set to VDD+3 volts, so that the voltage of VDD+3V less the threshold of the clamping transistor 772 passes from the global read data line “RDL” 712 to the sensing data line “SDL” 768.

The sensing data line “SDL” 768 is precharged to VDD+2V with a two-step precharge operation, first to VDD (e.g., 1.8V) and then, to VDD+2V by precharge signals PRE1_b and PRE2_b are fed to the transistors 761 and 763, respectively. During the Cell Development phase 970, the selected wordline is biased to 0V. The bias transistor 764 for the sensing data line “SDL” 768 is enabled. During this period, the selected cell (e.g., 304-(2,j)) will draw current and cause the sensing data line “SDL” 768 to change potential in accordance with the programmed state in that cell.

During the Data Sense phase 980, the sense amplifier senses the voltage at the sensing data line “SDL” 768 and causes SAout 782 to go high if the voltage at the sensing data line “SDL” 768 exceeds the reference voltage Vref. In one embodiment, the amplifier 766 latches the state of SAout 782 controlled by an additional control pin. In another embodiment, the amplifier 766 includes hysteresis, so that SAout 782 will not toggle when the sensing data line “SDL” 768 is equal to Vref 770 during the cell data development phase 970.

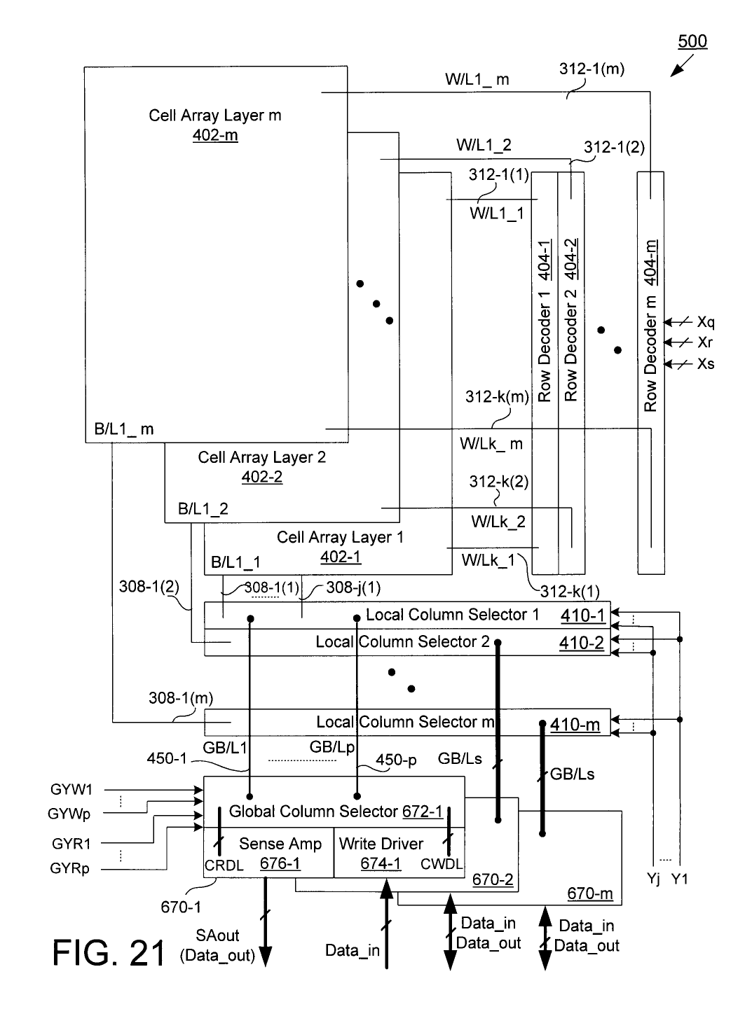

FIG. 21 shows a three-dimensional memory architecture according to another embodiment of the present invention. A three-dimensional memory architecture 500 shown in FIG. 21 is the same as that of that of FIG. 13A, except the global column operation circuits. Referring to FIG. 21, the three-dimensional memory architecture 500 includes m global column operation circuits 670-1, 670-2, . . . , 670-m, each of which has a global column selector, a write driver and a sense amplifier. In each of m global column operation circuits 670-1, 670-2, . . . , 670-m, the global column selector communicates with the write driver through common global write data lines “CWDLs”. The global column selector communicates with the sense amplifier through common global read data lines “CRDLs”. The write driver receives input data “Data_in” to be written into memory cells of PCM cell arrays. The sense amplifier provides output data read from memory cells of PCM cell arrays as “Data_out”. For example, the global column operation circuit 670-1 has a global column selector 672-1, a write driver 674-1 and a sense amplifier 676-1. The write driver 674-1 receives input data “Data_in” to be written into memory cells of PCM cell arrays. The sense amplifier 676-1 provides sense output “SAout” or “Data_out. Details of the other circuitry of the three-dimensional memory architecture 400 shown in FIG. 13A are applicable to the three-dimensional memory architecture 500 of FIG. 21.

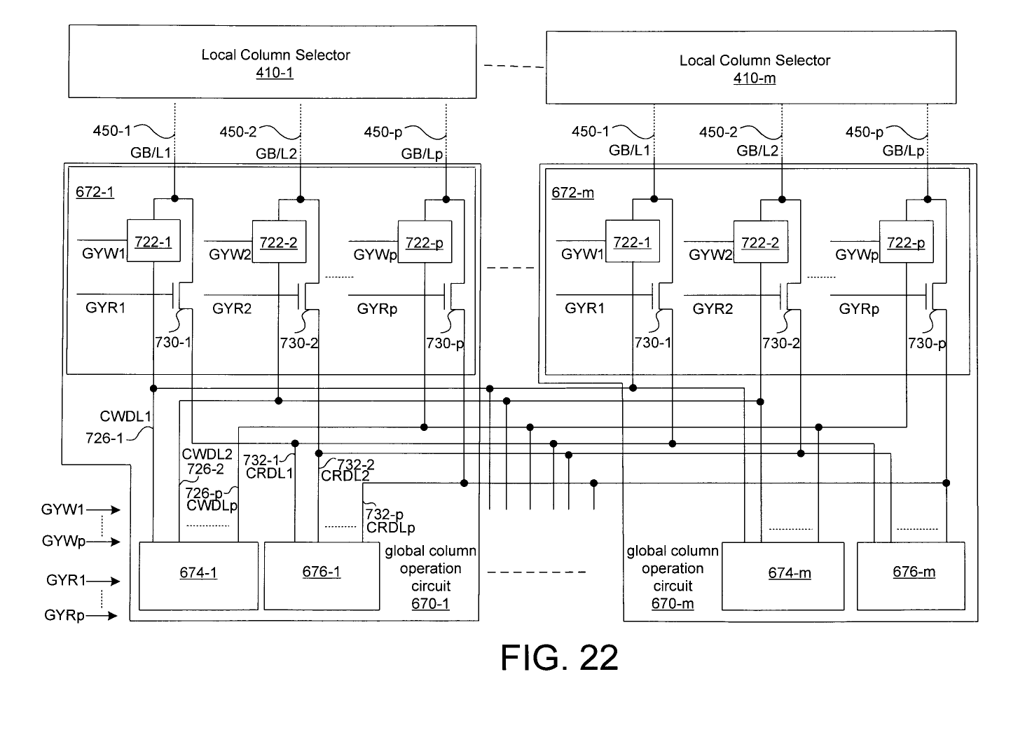

FIG. 22 shows an example of a global column selector. A global column selector shown in FIG. 22 is used in the three-dimensional memory architecture 500 shown in FIG. 21.

Referring to FIGS. 21 and 22, m global column selectors 672-1-672-m of the global column operation circuits 670-1-670-m have the same circuit structure and share global write data lines and global read data lines. The m global column selectors 672-1-672-m are connected to the local column selectors 410-1-410-m, respectively, through the respective group of p global bitlines “GB/L1”-“GB/L-p” 450-1-450-p. Each of the global column selectors 672-1-672-m includes p groups of a full CMOS transmission gate circuit for data writing and an NMOS transistor for data reading. For example, the global column selector 672-1 has p CMOS transmission gate circuits 722-1-722-p and p NMOS transistors 730-1-730-p. Similarly, the global column selector 672-m has p CMOS transmission gate circuits 722-1-722-p and p NMOS transistors 730-730-p. Each of the CMOS transmission gate circuits 722-1-722-p of each global column selector includes NMOS and PMOS transistors and an inverter with a control input as shown in FIG. 15.

In each of the global column selectors 672-1-672-m, the sources of the NMOS transistors 730-1-730-p and one of terminals of the CMOS transistor gate circuits 722-1-722-p are connected to the global bitlines 450-1-450-p, respectively. The global bitlines “GB/L1” 450-1 “GB/Lp” 450-p of each global column selector are connected to the respective local column selector. The other terminals of the CMOS transmission gate circuits 722-1 of the m global column selectors 672-1-672-m are connected to a common global write data line “CWDL1” 726-1. Similarly, the other terminals of the CMOS transmission gate circuits 722-p of the m global column selectors 672-1-672-m are connected to a common global write data line “CWDLp” 726-p. The drains of the NMOS transistors 730-1 of the m global column selectors 672-1-672-m are connected to a common global read data line “CRDL1” 732-1. Similarly, the drains of the NMOS transistors 730-p of the m global column selectors 672-1-672-m are connected to a common global read data line “CRDLp” 732-p. The common global write data lines “CWDL1”-“CWDLp” 726-1-726-p are commonly connected to the m write drivers 674-1-674-m. The common global read data lines “CRDL1”-“CRDLp” 732-1-732-p are commonly connected to the m sense amplifiers 676-1-676-m.

The global column selector 672-1, the write driver 674-1 and the sense amplifier 676-1 are included in the global column operation circuit 670-1. Similarly, the global column selector 672-m, the write driver 674-m and the sense amplifier 676-m are included in the global column operation circuit 670-m, as shown in FIG. 21. In the three-dimensional memory architecture 500 shown in FIG. 21, the common global write data lines “CWDL1” “CWDLp” 726-1-726-p and the common global read data lines “CRDL1”-“CRDLp” 732-1-732-p are shared by pairs of the write driver and the sense amplifier. The write driver 674-1 and the sense amplifier 676-1 can communicate with the global column selector other than the global column selector 672-1, for example, the global column selector 672-m associated with the local column selector 410-m. Therefore, the write driver 674-1 can write data into memory cells of PCM cell arrays formed on the cell array layer m, 402-m, shown in FIG. 21. Also, the sense amplifier 676-1 can read data from memory cells of PCM cell arrays of cell array layer m, 402-m. Similarly, the write driver 674-m and the sense amplifier 676-m can communicate with the global column selector 672-1 associated with the local column selector 410-1. Therefore, the write driver 674-m and the sense amplifier 676-m can access memory cells of PCM cell arrays formed on the cell array layer 1, 402-1.

The control inputs of the CMOS transmission gate circuits 722-1-722-p of the m global column selectors 672-1-672-m receive the write global column selection signals “GYW1”-“GYWp” during write operation. The gates of the NMOS transistors 730-1-730-p of the m global column selectors 672-1-672-m receive the read global column selection signals “GYR1”-“GYRp” during read operation. The global column selector 672 shown in FIG. 22 is advantageous, because the common global write data lines “CWDLs” 726-1-726-p and the common read data lines “CRDLs” 732-1-732-p are shared by the m global column selectors 672-1-672-m. The global column selectors 672-1-672-m communicate with any one of the write drivers 674-1-674-m through the common global read data lines “CRDLs” and any one of the sense amplifiers 676-1-676-m through the common global read data lines “CRDLs” in and between the global column operation circuits 670-1-670-m.

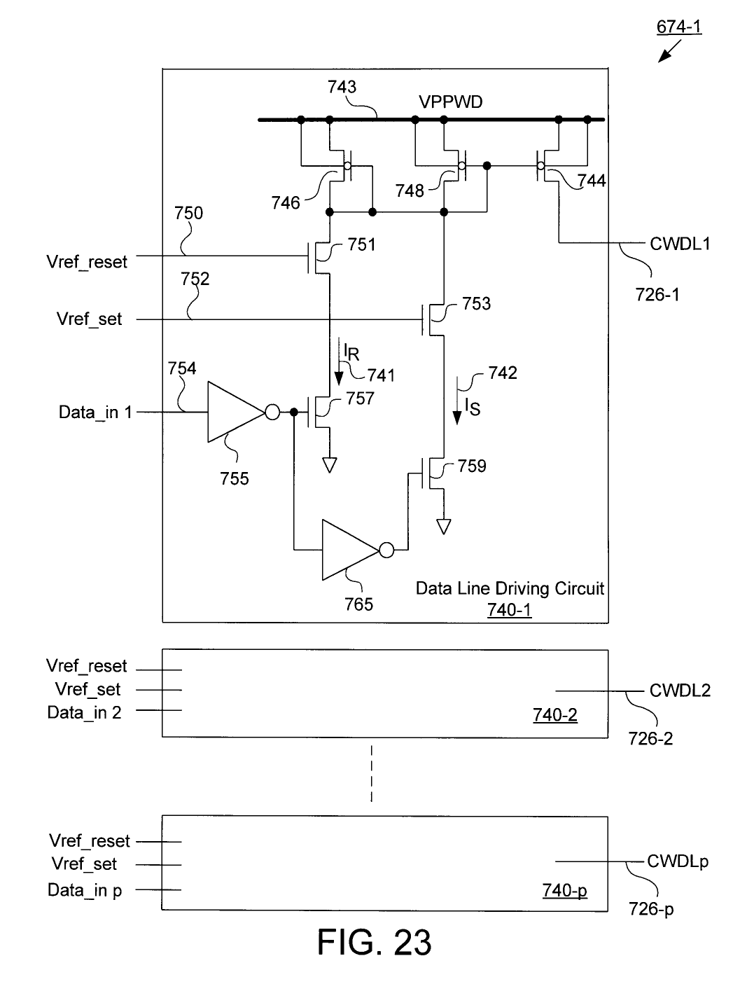

FIG. 23 shows an example of the write driver for use in the global column operation circuit shown in FIG. 21. Referring to FIG. 23, the write driver 674-1 has p data line driving circuits 740-1-740-p which are connected to the respective common global write data lines “CWDL1”-“CWDLp” 726-1-726-p. The p data line driving circuits 740-1-740-p receive input data “Data_in 1”-“Data_in p” and provide current to the respective common global write data lines “CWDL1”-“CWDLp”. The operation of the write driver 674-1 is similar to that of the write driver 474 shown in FIG. 16.

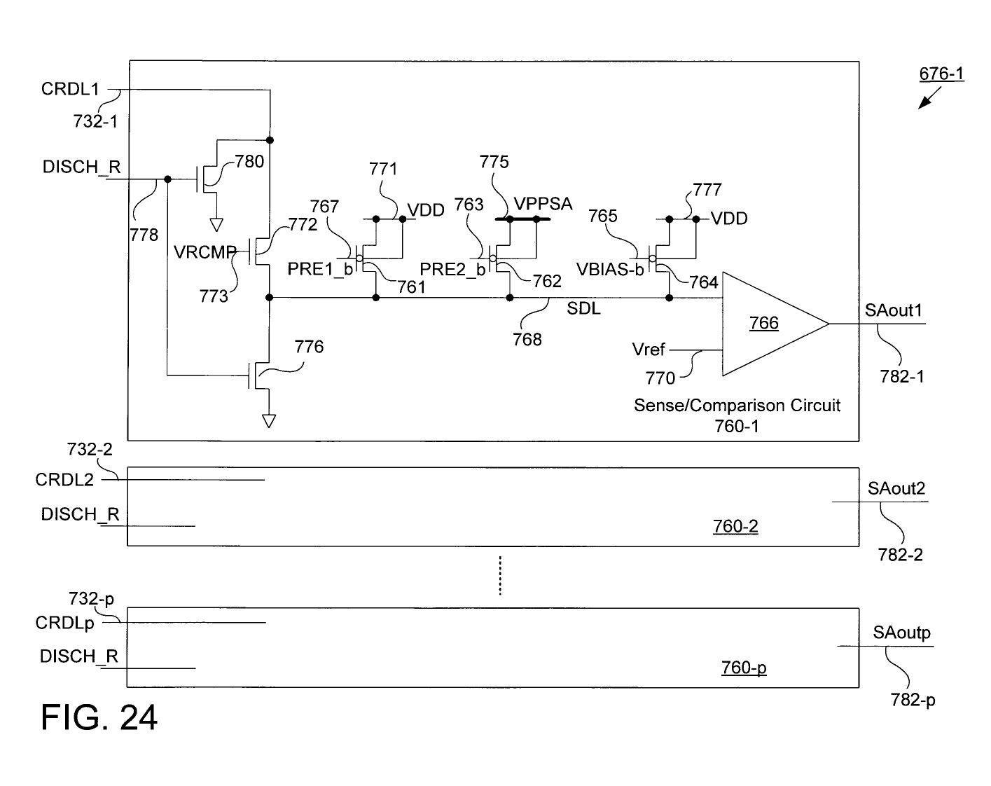

FIG. 24 shows an example of the sense amplifier for use in the global column operation circuit shown in FIG. 21. Referring to FIG. 24, the sense amplifier 674-1 has p sense/comparison circuits 760-1-760-p which are connected to the respective common global read data lines “CRDL1”-“CRDLp” 732-732-p. The sense/comparison circuits 760-1-760-p receive signals representing read data through the common global read data lines “CRDL1”-“RDL-p” 732-1-732-p and provides the SAout 1-SAout p as the data out “Data_out” from the sense outputs 782-1-782-p, respectively. The operation of the sense amplifier 676-1 is similar to that of the sense amplifier 476 shown in FIG. 17.

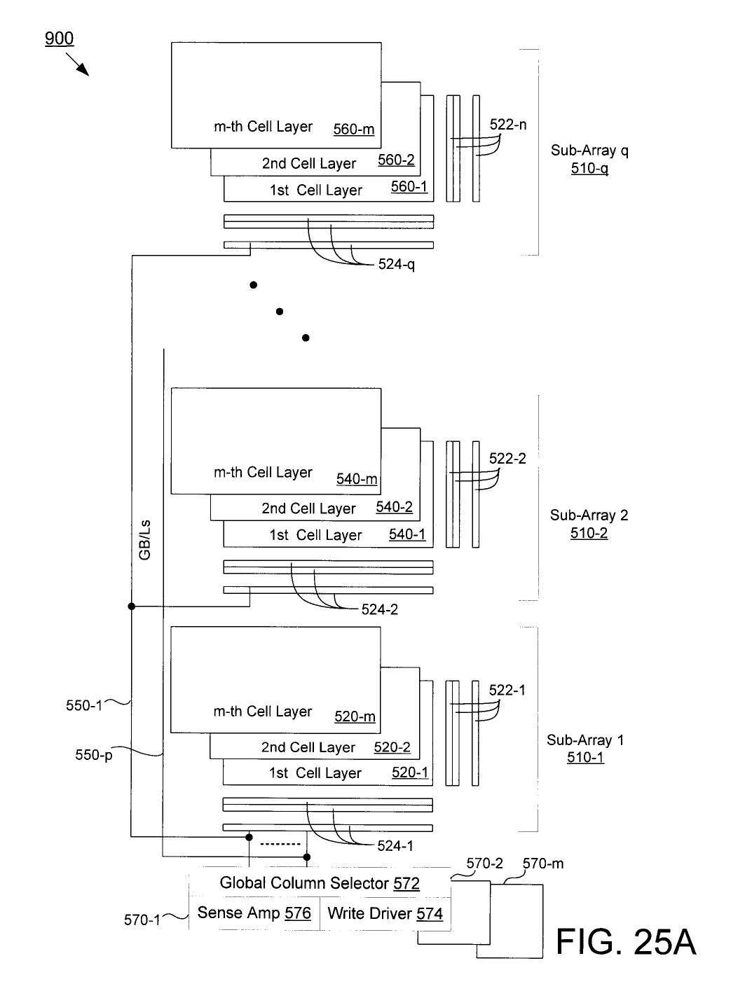

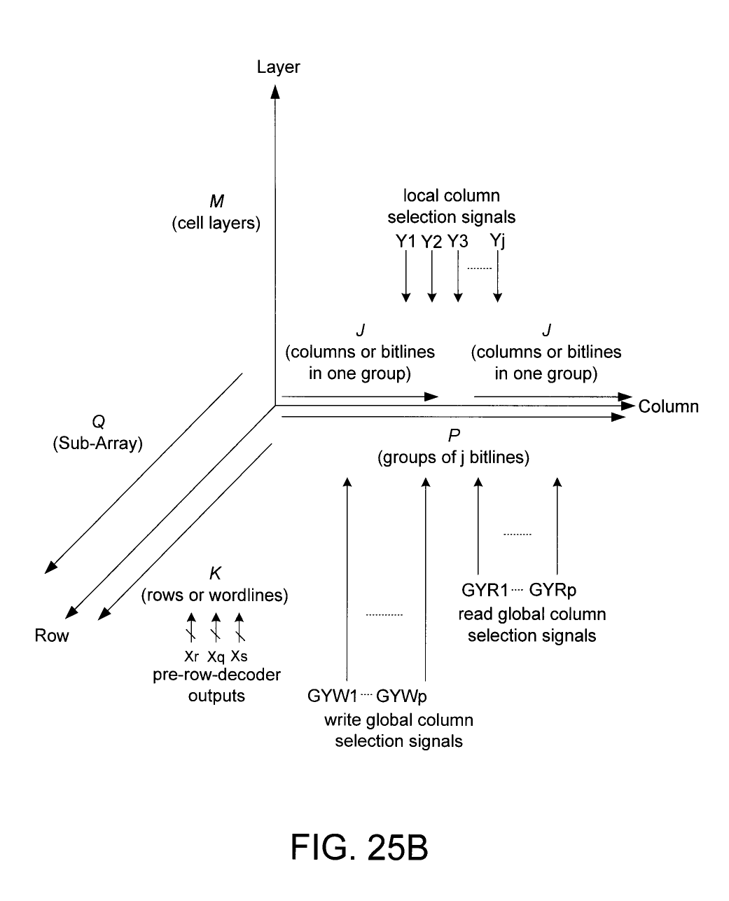

FIG. 25A shows a three-dimensional phase change memory (PCM) architecture according to another embodiment of the present invention. Referring to FIG. 25A, a three-dimensional memory architecture 900 includes segmented cell arrays (sub-array 1, 2, . . . , q) of m layers. Each of the sub-arrays includes a plurality of cell arrays. Sub-array 510-1 includes cell arrays 520-1, 520-2, . . . , 520-m formed on respective ones of m layers. Similarly, the sub-array 510-2 includes cell arrays 540-1, 540-2, . . . , 540-m formed on respective ones of m layers. The sub-array 510-q includes cell arrays 560-1, 560-2, . . . , formed on respective ones of m layers. In the three-dimensional memory architecture 900, row decoders 522-1, 522-2, . . . , 522-q are associated with the sub-arrays 510-1, 510-2, . . . , 510-q, respectively. Similarly, local column selectors 524-1, 524-2, . . . , 524-q are associated with the sub-arrays 510-1, 510-2, . . . , 510-q, respectively. Furthermore, the three-dimensional memory architecture 900 includes a plurality of (m) global column operation circuits 570-1, 570-2, . . . , 570-m that communicate with the local column selectors 524-1-524-q. Each of the m global column operation circuits 570-1, 570-2, . . . , 570-m has a global column selector 572, a write driver 574 and a sense amplifier 576. The global column selector 572 of each of the global column operation circuits 570-1, 570-2, . . . , 570-m is connected to the corresponding local column selectors 524-1, 524-2, . . . , 524-q through the global bitlines (B/Ls) 550-1-550-p. To control operations of the three-dimensional memory architecture 900, the same address signals are provided as those of the three-dimensional stacked memory device architecture 400 shown in FIG. 13A.

FIG. 25B shows memory address control signals for the three-dimensional memory architecture shown in FIG. 25A. In the three-dimensional memory architecture 900, the cell arrays of each layer are divided by q to the q sub-arrays 510-1-510-q. Therefore, a signal representing identification “Q” (1≦Q≦q) of a selected sub-array is used in addition to the signals representing the identifications (“J”, “P”, “K”, “M”).

The row decoders 522-1, 522-2, . . . , 522-q are formed on the same semiconductor layer as the local column selectors 524-1, 524-2, . . . , 524-q, in addition to global column selectors 572, write driver 574 and sense amplifiers 576. The global bitlines (B/Ls) 550-1-550-p run over q sub-arrays 510a-510-q. For example, the global bitlines (B/Ls) 550-1-550-p are implemented in a conducive (metal) layer other the conductive layers of the wordlines and the bitlines. The global bitlines connect the local column selectors and the global column selector used with each sub-array as shown in FIG. 25A. Similar to the three-dimensional stacked memory device architecture 400 shown in FIG. 13A, all of the row decoders 522-1, 522-2, . . . , 522-q, the local column selectors 524-1, 524-2, . . . , 524-q, the global column selectors 572, the write drivers 574 and the sense amplifiers 576 are formed on the same semiconductor layer. Part of them may be formed in different layers.

In one embodiment, all of the row decoders 522-1-522-q are formed adjacent on the same layer. Advantageously, this arrangement of row decoders optimizes layout density because each row decoder is of a similar height. In one embodiment, all of the local column selectors 524-1, 524-2, . . . , 524-q are formed side-by-side on the same layer. Advantageously, this arrangement of local column selectors optimizes layout density because each local column selector is of a similar height.

In response to the signals, peripheral circuitry controls operations of the memory device of the three-dimensional PCM architecture. Memory control circuitry (not shown) provides the identification signals for identifying or selecting specific PCM cells in the three-dimensional PCM architecture according to embodiments of the present invention.

In the above mentioned memory cells of the embodiments and examples, implemented are diode based PCM cells as shown in FIG. 5. Diodes are two-terminal switching elements. The PMC cells of the FET based PCM cell shown in FIG. 6 and the bipolar transistor based PCM cells shown in FIG. 7 can be implemented. Such implementations as FET and bipolar based PCM cells need replace the vertical P-N diode as the anode 186 and the cathode 188 shown in FIG. 9A to form the emitter, base of a bipolar transistor and the drain, gate of a P-channel FET, the collector of the bipolar transistor and the source of the FET being grounded. Because bipolar transistors and FETs are three-terminal switching elements, circuit structures of controlling bipolar and FET based PCM cells may be different from those of the diode based PCM cells.

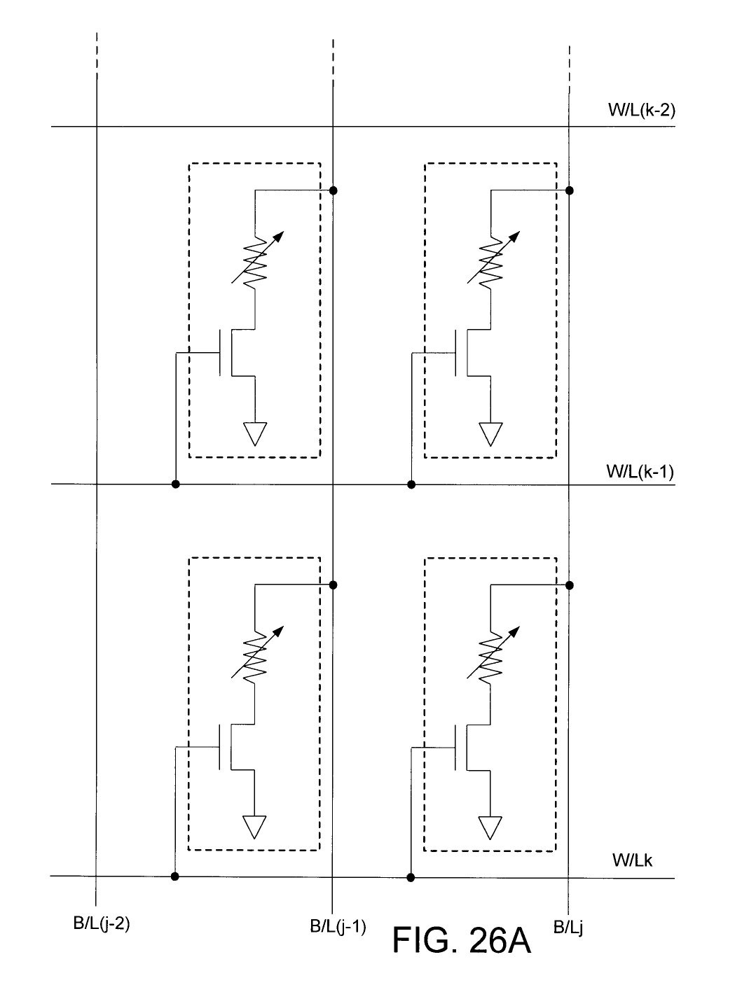

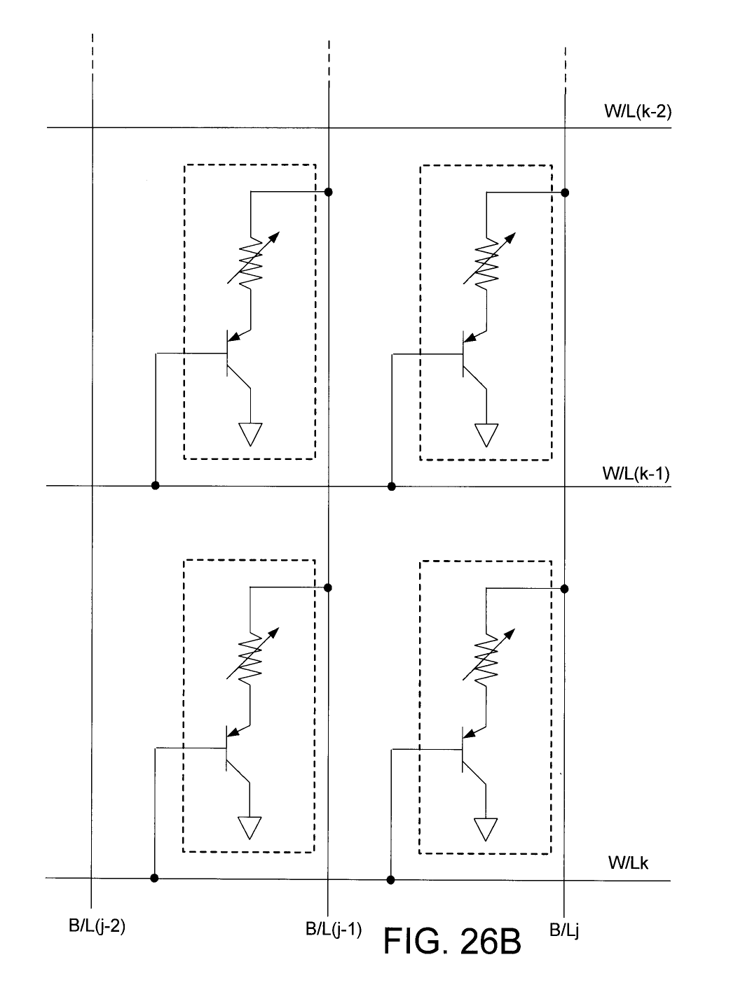

FIGS. 26A and 26B show other examples of PCM cell arrays applicable to memory devices according to embodiments of the present invention. A memory cell array shown in FIG. 26A includes a plurality of PCM cells including FETs as switching elements. A memory cell array shown in FIG. 26B includes a plurality of PCM cells including bipolar transistors as switching elements.

According to the embodiments of the present invention, there is provided a three-dimensional phase change memory device; phase change memory device architecture for three-dimensional multiple stacked memory cell arrays with shared controlled circuits, design techniques for phase change memory device having three-dimensional multiple stacked memory cell arrays. In the embodiments, specific circuits, devices and elements are used as examples. Various alterations can be implemented. For example, the polarity of devices and voltage may be changed and bipolar transistors and FETs having opposite polarity may be used.

In the embodiments described above, the device elements and circuits are connected to each other as shown in the figures, for the sake of simplicity. In practical applications of the present invention, elements, circuits, etc. may be connected directly to each other. As well, elements, circuits etc. may be connected indirectly to each other through other elements, circuits, etc., necessary for operation of devices and apparatus. Thus, in actual configuration, the circuit elements and circuits are directly or indirectly coupled with or connected to each other.

The above-described embodiments of the present invention are intended to be examples only. Alterations, modifications and variations may be effected to the particular embodiments by those of skill in the art without departing from the scope of the invention, which is defined solely by the claims appended hereto.

1. A method of fabricating a memory device comprising:
forming a stack of semiconductor layers;
forming a circuit on a layer of the stack of semiconductor layers;
forming a primary memory array on another layer of the stack of semiconductor layers different from the layer comprising the circuit; and
forming a plurality of electrical communication paths between the circuit and the primary memory array, the circuit controlling operation of the primary memory array over the electrical communication paths.

2. The method of claim 1, wherein forming a primary memory array includes one of:
forming a phase change memory; and
forming a phase change memory comprising a plurality of memory cells, each memory cell including a diode connected to a variable resistive element.

3. The method of claim 1, further comprising forming a secondary memory array on the layer comprising the circuit.

4. The method of claim 1, wherein forming a stack of semiconductor layers includes: forming the layer comprising the circuit before forming the layer comprising the primary memory array.

5. The method of claim 1, further comprising one of:
forming a memory array on each layer of the stack of semiconductor layers; and
forming a memory array on each layer of the stack of semiconductor layers, each layer being different from the layer including the circuit.

6. A memory device comprising:
a stack of semiconductor layers;
a circuit on a layer of the stack of semiconductor layers;
a primary memory array on another layer of the stack of semiconductor layers different from the layer comprising the circuit; and
a plurality of electrical communication paths between the circuit and the primary memory array, the circuit controlling operation of the primary memory array over the electrical communication paths.

7. The memory device of claim 6, wherein the primary memory array comprises one of:
a phase change memory; and
a plurality of memory cells.

8. The memory device of claim 6, wherein each of the plurality of memory cells comprise one of:
a diode connected to a variable resistive element;
a field-effect transistor connected to a variable resistive element; and
a bipolar transistor connected to a variable resistive element.

9. The memory device of claim 6, wherein the layer comprising the circuit further comprises a memory array.

10. The memory device of claim 6, wherein the layer including the circuit is the first layer formed in the stack of semiconductor layers.

11. The memory device of claim 6, wherein each layer of the stack of semiconductor layers comprises a memory array.

12. The memory device of claim 6, further comprising a memory array on each layer of the stack of semiconductor layers, each layer being different from the layer including the circuit.

13. A memory device comprising:
a base semiconductor layer comprising a plurality of memory control circuits; and
a stack of semiconductor layers formed over the base semiconductor layer, each layer of the stack of semiconductor layers including a memory array in communication with one of the plurality of memory control circuits.

14. The memory device of claim 13, wherein each memory array comprises one of:
a phase change memory comprising a plurality of memory cells, each memory cell including a diode connected to a variable resistive element; and
a phase change memory comprising a plurality of memory cells, each memory cell including a field-effect transistor connected to a variable resistive element.

15. The memory device of claim 14, wherein each memory array comprises a phase change memory including a plurality of memory cells, each memory cell having a bipolar transistor connected to a variable resistive element.

16. A memory device comprising:
a stack of m layers, each layer including an array of memory cells formed thereon, the array having k rows×c columns of cells, each of m, k and c being an integer greater than one, each of the memory cells including a phage change memory cell; and
peripheral circuitry for controlling operation of the memory cells formed on one of the layers.

17. The memory device of claim 16, wherein the peripheral circuitry and the memory cell array on one of the layers are formed on a common semiconductor substrate.

18. The memory device of claim 17, wherein the peripheral circuitry comprises m row selectors corresponding to the m layers, each of the m row selectors controlling row selection of the memory cells formed on the corresponding layer.

19. The memory device of claim 18, wherein the peripheral circuitry further comprises m column selectors corresponding to the m layers, each of the m column selectors controlling column selection of the memory cells formed on the corresponding layer.

20. The memory device of claim 19, wherein the peripheral circuitry further comprises p global column selectors, each controlling the column selection of the m column selectors.

21. The memory device of claim 16, wherein the memory array of memory cells on each of the m layers are divided into a plurality of sub-arrays.

22. The memory device of claim 16, wherein the c columns of each layer are grouped by j columns to form p groups, c being equal to j×p.

23. The memory device of claim 22, wherein the p global column selectors respond to global column selection signals for selecting a global column.

24. The memory device of claim 23, wherein the p column selectors, associated with the selected global column, respond to local column selection signals for selecting a column of the array.

25. The memory device of claim 24, wherein each of the m row selectors responds to row selection signals for selecting a row of the array.

26. The memory device of claim 25, wherein the memory cell in the selected row and column of the array operates with data write and read.

27. The memory device of claim 22, wherein the m column selectors comprising selection operation transistors and discharging operation transistors, the selection operation transistors being coupled to the j columns, the discharging operation transistors being coupled to the selection operation transistors, the discharging operation transistors performing discharge the columns before accessing the memory cell.

28. The memory device of claim 22, wherein the periphery circuitry further comprises data write circuitry for writing data to the memory cell in the selected row and column of the cell array.

29. The memory device of claim 22, wherein the periphery circuitry further comprises data read circuitry for reading data from the memory cell in the selected row and column of the cell array.

30. The memory device of claim 29, wherein the data read circuitry comprises a data read discharging transistor for discharging a line for reading the data before data reading.

31. The memory device of claim 30, wherein the data read circuitry further comprises:
a precharging operation transistor for precharging a data sensing operation line; and
a cramping operation transistor for developing a voltage on the data sensing operation line in response to data voltage.

32. The memory device of claim 31, wherein the data read circuitry further comprises circuitry for performing a plurality of steps for performing the precharging of the data sensing operation line.

33. The memory device of claim 31, wherein the data read circuitry further comprises a comparator for comparing a voltage developed on the data sensing operation line to a reference voltage, the comparator providing a read data output whether the developed voltage is greater than the reference voltage.
